(19) United States
(12) Patent Application Publication
(10) Pub. No.: US 2026/0063734 A1
(43) Pub. Date: Mar. 5, 2026

(54) RADIO FREQUENCY MAGNETIC SENSOR FOR MAGNETIC FIELD COMMUNICATION AND MANUFACTURING METHOD OF THE SAME

(71) Applicant: ELECTRONICS AND TELECOMMUNICATIONS RESEARCH INSTITUTE, Daejeon (KR)

(72) Inventors: Jang Yeol KIM, Daejeon (KR); In Kui CHO, Daejeon (KR); Jung Hoon OH, Daejeon (KR); Kyeseok YOON, Daejeon (KR); Hyunjoon LEE, Daejeon (KR)

(73) Assignee: ELECTRONICS AND TELECOMMUNICATIONS RESEARCH INSTITUTE, Daejeon (KR)

(21) Appl. No.: 19/030,683

(22) Filed: Jan. 17, 2025

(30) Foreign Application Priority Data
Sep. 3, 2024 (KR) 10-2024-0119393

(51) Int. Cl. G01R 33/06; G01R 33/00; H04B 5/26

(52) U.S. Cl. CPC G01R 33/063; G01R 33/0005; G01R 33/0052; H04B 5/26

(57) ABSTRACT

A radio frequency (RF) magnetic sensor for magnetic field communication may comprise: a first RF magnetic sensor; a second RF magnetic sensor; a first inner protective case into which the first RF magnetic sensor is inserted and with which the first RF magnetic sensor is combined; a second inner protective case into which the second RF magnetic sensor is inserted and with which the second RF magnetic sensor is combined; a fixing jig in which the first inner protective case is coupled by penetrating in a first direction, and the second inner protective case is coupled by penetrating in a second direction perpendicular to the first direction; and an outer case for protecting the fixing jig by enclosing the fixing jig inside.

### CROSS-REFERENCE TO RELATED APPLICATIONS

This application claims priority to Korean Patent Application No. 10-2024-0119393, filed on Sep. 3, 2024, with the Korean Intellectual Property Office (KIPO), the entire contents of which are hereby incorporated by reference.

### BACKGROUND

### 1. Technical Field

The present disclosure relates to a radio frequency (RF) magnetic sensor for magnetic field communication and a technique for manufacturing the same, and more particularly, to an RF magnetic sensor used as a receiving element for magnetic field communication in wireless communication under extreme environments and manufacturing method of the same.

### 2. Related Art

Typically, types of magnetic sensors include fluxgate sensors, Hall sensors, magneto-resistive sensors, giant magneto-impedance (GMI) sensors, magnetic induction (MI) sensors, and SQUID sensors, and the like.

To utilize magnetic sensors as receiving sensors in extreme environments such as underwater or underground, it is required to detect weak magnetic field (magnetic flux density) communication signals. Therefore, these sensors need to exhibit ultra-high sensitivity and robustness against noise. In particular, to extend a communication range in VLF/LF bands from several tens of meters to hundreds of meters, RF magnetic sensors are required, and ultra-high sensitivity characteristics of these RF magnetic sensors are essential.

Sensors with ultra-high sensitivity can achieve sensitivity levels in a pico-tesla range. For example, such ultra-high sensitivity sensors include fluxgate sensors, giant magneto-impedance sensors, magnetic induction sensors, and SQUID sensors.

In underwater and underground environments where a transmitter and receiver are located in different positions, the receiver needs to detect communication signals transmitted by the transmitter. Since a direction from which the communication signals are transmitted cannot be known, an RF magnetic sensor capable of omnidirectional detection is required for the receiver.

### SUMMARY

The present disclosure for resolving the above-described problems is directed to providing two-axis and three-axis magnetic sensors capable of receiving transmitted communication signals in all directions or facilitating signal reception from a specific direction during magnetic field communication in extreme environments (underwater or underground), and a manufacturing method of the same.

The present disclosure for resolving the above-described problems is also directed to providing two-axis and three-axis RF magnetic sensors for magnetic field communication, capable of detecting RF communication signals in all directions while increasing a transmission range to enable medium- to long-distance magnetic field communication, and a manufacturing method of the same.

According to a first exemplary embodiment of the present disclosure, a radio frequency (RF) magnetic sensor for magnetic field communication may comprise: a first RF magnetic sensor; a second RF magnetic sensor; a first inner protective case into which the first RF magnetic sensor is inserted and with which the first RF magnetic sensor is combined; a second inner protective case into which the second RF magnetic sensor is inserted and with which the second RF magnetic sensor is combined; a fixing jig in which the first inner protective case is coupled by penetrating in a first direction, and the second inner protective case is coupled by penetrating in a second direction perpendicular to the first direction; and an outer case for protecting the fixing jig by enclosing the fixing jig inside.

The RF magnetic sensor may further comprise: a third RF magnetic sensor; and a third inner protective case, wherein the third RF magnetic sensor is inserted into and combined with the third inner protective case, and the third inner protective case is coupled with the fixing jig by penetrating the fixing jig in a third direction respectively perpendicular to the first direction and the second direction.

One inner protective case of the first inner protective case or the second inner protective case may include a body and a rear cover combined with a first side among both sides of the body, a first insertion hole for inserting an RF magnetic sensor of the one inner protective case may be formed on the first side of the body, with which the rear cover is combined, a third through-hole extended from the first insertion hole may be formed on the rear cover, the RF magnetic sensor of the one inner protective case may be inserted into the first insertion hole, and an output terminal of the RF magnetic sensor of the one inner protective case may penetrates the third through-hole.

The one inner protective case may further include a front cover combined with a second side among the both sides of the body, the first insertion hole may extend to the second side of the body to form a first through-hole, the front cover may have a second through-hole formed extending from the first through-hole on the second side of the body, and the output terminal and an input terminal of the RF magnetic sensor inserted into the first through-hole of the body may be respectively arranged through the third through-hole of the rear cover and the second through-hole of the front cover.

The outer case may include a cover plate and a bottom plate, at least one of input ports or output ports for each of the first RF magnetic sensor and the second RF magnetic sensor may be formed on one side of the cover plate, and at least one of the input ports and output ports may be connected to a corresponding input terminal or output terminal of the first RF magnetic sensor and the second RF magnetic sensor via an RF cable.

The first RF magnetic sensor and the second RF magnetic sensor may be RF magnetic sensors based on a giant magneto-impedance (GMI) scheme or a magnetic induction scheme.

Materials of the first inner protective case, the second inner protective case, and the fixing jig may include a non-magnetic material.

One RF magnetic sensor of the first RF magnetic sensor or the second RF magnetic sensor may include a first sub-RF magnetic sensor and a second sub-RF magnetic sensor connected to a single substrate, a first end among both ends of a first pickup coil surrounding a ferromagnetic core of the first sub-RF magnetic sensor may be connected to an output terminal of the first sub-RF magnetic sensor, and a second end among both ends of a second pickup coil surrounding a ferromagnetic core of the second sub-RF magnetic sensor, which corresponds to a second end among the both ends of the first pickup coil, may be connected to an output terminal of the second sub-RF magnetic sensor.

One RF magnetic sensor of the first RF magnetic sensor or the second RF magnetic sensor may be a dual RF magnetic sensor, and the dual RF magnetic sensor may include: two ferromagnetic cores connected to a single substrate and two pickup coils each surrounding the two ferromagnetic cores, a first end among both ends of a first pickup coil surrounding a first ferromagnetic core among the two ferromagnetic cores may be connected to an output terminal of the dual RF magnetic sensor, and a first end among both ends of a second pickup coil surrounding a second ferromagnetic core among the two ferromagnetic cores, which corresponds to the first end of the first pickup coil, may be connected to the output terminal of the dual RF magnetic sensor.

One RF magnetic sensor among the first RF magnetic sensor and the second RF magnetic sensor may further include a second dual RF magnetic sensor connected to the substrate, a second end among both ends of a first pickup coil of the second dual RF magnetic sensor, which corresponds to a second end among the both ends of the first pickup coil of the dual RF magnetic sensor, may be connected to an output terminal of the second dual RF magnetic sensor, and a second end among both ends of a second pickup coil of the second dual RF magnetic sensor may be connected to the output terminal of the second dual RF magnetic sensor.

According to a second exemplary embodiment of the present disclosure, a method for manufacturing a radio frequency (RF) magnetic sensor for magnetic field communication may comprise: inserting a first RF magnetic sensor into a first inner protective case; inserting a second RF magnetic sensor into a second inner protective case; coupling the first inner protective case with a fixing jig by penetrating the first inner protective case into a first fixing jig through-hole formed in a first direction of the fixing jig; coupling the second inner protective case with the fixing jig by penetrating the second inner protective case into a second fixing jig through-hole formed in a second direction perpendicular to the first direction of the fixing jig; and installing an outer case on the fixing jig.

The method may further comprise: inserting a third RF magnetic sensor into a third inner protective case; and coupling the third inner protective case with the fixing jig by penetrating the third inner protective case into a third fixing jig through-hole formed in a third direction respectively perpendicular to the first direction and the second direction of the fixing jig.

The first inner protective case may include a body in which a first insertion hole is formed, and a rear cover that is combined with a first side among both sides of the body where the first insertion hole is formed and has a third through-hole, and the inserting of the first RF magnetic sensor into the first inner protective case may comprise: inserting the first RF magnetic sensor into the first insertion hole of the body; and combining the rear cover with the body by inserting an output terminal of the first RF magnetic sensor, which is exposed from the body, into the third through-hole.

The first inner protective case may further include a front cover that is connected with a second side of the both sides of the body and has a second through-hole, and the inserting of the first RF magnetic sensor into the first inner protective case may comprise: combining the front cover with the body by inserting an input terminal of the first RF magnetic sensor, which is exposed from the second side of the body, into the second through-hole.

The outer case may include a cover plate and a bottom plate, and at least one of input ports or output ports for each of the first RF magnetic sensor and the second RF magnetic sensor may be formed on one side of the cover plate, and the installing of the outer case on the fixing jig may comprise: positioning the fixing jig on the bottom plate and combining the bottom plate with the cover plate; and connecting at least one of the input ports and output ports to a corresponding input terminal or output terminal of the first RF magnetic sensor or the second RF magnetic sensor via an RF cable.

The first RF magnetic sensor and the second RF magnetic sensor may be RF magnetic sensors based on a giant magneto-impedance (GMI) scheme or a magnetic induction scheme.

Materials of the first inner protective case, the second inner protective case, and the fixing jig may include a non-magnetic material.

The method may further comprise: before inserting the first RF magnetic sensor into the first inner protective case, manufacturing each of the first RF magnetic sensor and the second RF magnetic sensor, wherein the manufacturing may comprise: connecting a first sub-RF magnetic sensor to a substrate such that a first end among both ends of a first pickup coil surrounding a ferromagnetic core of the first sub-RF magnetic sensor is connected to an output terminal of the first sub-RF magnetic sensor; and connecting a second sub-RF magnetic sensor to the substrate such that a second end among both ends of a second pickup coil surrounding a ferromagnetic core of the second sub-RF magnetic sensor, which corresponds to a second end among the both ends of the first pickup coil, is connected to an output terminal of the second sub-RF magnetic sensor.

The method may further comprise: when one RF magnetic sensor of the first RF magnetic sensor or the second RF magnetic sensor includes one dual RF magnetic sensor, manufacturing the dual RF magnetic sensor before inserting the first RF magnetic sensor into the first inner protective case, wherein the manufacturing of the dual RF magnetic sensor may comprise: connecting a first ferromagnetic core around which a first pickup coil is wound to a substrate; connecting a first end among both ends of the first pickup coil to an output terminal of the dual RF magnetic sensor; connecting a second ferromagnetic core around which a second pickup coil is wound to the substrate; and connecting a first end among both ends of the second pickup coil, which corresponds to the first end of the first pickup coil, to the output terminal of the dual RF magnetic sensor.

The method may further comprise: when one RF magnetic sensor of the first RF magnetic sensor and the second RF magnetic sensor further includes a second dual RF magnetic sensor, manufacturing the one dual RF magnetic sensor before inserting the first RF magnetic sensor into the first inner protective case, wherein the manufacturing of the one RF magnetic sensor may comprise: connecting a first ferromagnetic core around which a first pickup coil of the second dual RF magnetic sensor is wound to the substrate, and connecting a second ferromagnetic core around which a second pickup coil of the second dual RF magnetic sensor is wound to the substrate; connecting a second end among both ends of the first pickup coil of the second dual RF magnetic sensor, which corresponds to a second end among both ends of the dual RF magnetic sensor, to an output terminal of the second dual RF magnetic sensor; and connecting a second end among both ends of the second pickup coil of the second dual RF magnetic sensor, which corresponds to a second end among both ends of the first pickup coil of the second dual RF magnetic sensor, to the output terminal of the second dual RF magnetic sensor.

According to the present disclosure, two-axis and three-axis magnetic sensors and their manufacturing methods can be provided, which enable reception of transmitter's communication signals from all directions or facilitate reception of transmitter's communication signals from a specific direction when magnetic field communication is performed in extreme environments (e.g. underwater, underground, etc.).

According to the present disclosure, two-axis and three-axis RF magnetic sensors for magnetic field communication and their manufacturing methods can be provided, which can detect RF communication signals from all directions while increasing a transmission distance to enable medium-to-long distance magnetic field communication.

### BRIEF DESCRIPTION OF DRAWINGS

FIG. 1 is a flowchart illustrating a method for manufacturing an RF magnetic sensor according to an exemplary embodiment of the present disclosure.

FIG. 2 illustrates both sides of a basic 1-axis magnetic sensor using the GMI scheme according to an exemplary embodiment of the present disclosure.

FIG. 3 illustrates an equivalent electrical circuit of the 1-axis magnetic sensor illustrated in FIG. 2.

FIG. 4 is a diagram illustrating a differential RF magnetic sensor using the GMI scheme according to an exemplary embodiment of the present disclosure.

FIG. 5 is another diagram illustrating a differential RF magnetic sensor using the GMI scheme according to an exemplary embodiment of the present disclosure.

FIG. 6 is a graph illustrating output voltage characteristics, among the performance characteristics of the basic and differential RF magnetic sensors using the GMI scheme according to an exemplary embodiment of the present disclosure.

FIG. 7 is a graph illustrating magnetic noise characteristics, among the performance characteristics of the basic and differential RF magnetic sensors using the GMI scheme according to an exemplary embodiment of the present disclosure.

FIG. 8 is a diagram illustrating a manufacturing process of a two-axis RF magnetic sensor using the GMI scheme according to an exemplary embodiment of the present disclosure.

FIG. 9 is another diagram illustrating the manufacturing process of the two-axis RF magnetic sensor using the GMI scheme according to an exemplary embodiment of the present disclosure.

FIG. 10 is a diagram illustrating a housing and input/output ports of the two-axis RF magnetic sensor using the GMI scheme according to an exemplary embodiment of the present disclosure.

FIG. 11 is a diagram illustrating a manufacturing process of a three-axis RF magnetic sensor using the GMI scheme according to an exemplary embodiment of the present disclosure.

FIG. 12 is another diagram illustrating the manufacturing process of the three-axis RF magnetic sensor using the GMI scheme according to an exemplary embodiment of the present disclosure.

FIG. 13 is a diagram illustrating a housing and input/output ports of the three-axis RF magnetic sensor using the GMI scheme according to an exemplary embodiment of the present disclosure.

FIG. 14 illustrates both sides of a basic single-axis magnetic sensor based on the MI scheme according to an exemplary embodiment of the present disclosure.

FIG. 15 illustrates both sides of a basic single-axis magnetic sensor based on the MI scheme according to another exemplary embodiment of the present disclosure.

FIG. 16 illustrates both sides of a dual RF magnetic sensor based on the MI scheme according to an exemplary embodiment of the present disclosure.

FIG. 17 illustrates both sides of a dual RF magnetic sensor using the MI scheme according to another exemplary embodiment of the present disclosure.

FIG. 18 is a diagram illustrating a differential RF magnetic sensor using the MI scheme according to an exemplary embodiment of the present disclosure.

FIG. 19 is a diagram illustrating a dual differential RF magnetic sensor using the MI scheme according to another exemplary embodiment of the present disclosure.

FIG. 20 is a graph illustrating output voltage characteristics, among the performance characteristics, of RF magnetic sensors using the MI scheme according to an exemplary embodiment of the present disclosure.

FIG. 21 is a graph illustrating magnetic noise characteristics, among the performance characteristics, of RF magnetic sensors using the MI scheme according to an exemplary embodiment of the present disclosure.

FIG. 22 is a diagram illustrating a manufacturing process of a two-axis RF magnetic sensor using the MI scheme according to an exemplary embodiment of the present disclosure.

FIG. 23 is another diagram illustrating the manufacturing process of the two-axis RF magnetic sensor using the MI scheme according to an exemplary embodiment of the present disclosure.

FIG. 24 is a diagram illustrating a housing and input/output ports of the two-axis RF magnetic sensor using the MI scheme according to an exemplary embodiment of the present disclosure.

FIG. 25 is a diagram illustrating a manufacturing process of a three-axis RF magnetic sensor using the MI scheme according to an exemplary embodiment of the present disclosure.

FIG. 26 is another diagram illustrating the manufacturing process of the three-axis RF magnetic sensor using the MI scheme according to an exemplary embodiment of the present disclosure.

FIG. 27 is a diagram illustrating a housing and input/output ports of the three-axis RF magnetic sensor using the MI scheme according to an exemplary embodiment of the present disclosure.

FIG. 28 is a graph illustrating output voltage characteristics of a three-axis RF magnetic sensor using the MI scheme according to an exemplary embodiment of the present disclosure.

FIG. 29 is a flowchart illustrating a manufacturing method of an RF magnetic sensor for magnetic field communication according to an exemplary embodiment of the present disclosure.

### DETAILED DESCRIPTION OF THE EMBODIMENTS

Since the present disclosure may be variously modified and have several forms, specific exemplary embodiments will be shown in the accompanying drawings and be described in detail in the detailed description. It should be understood, however, that it is not intended to limit the present disclosure to the specific exemplary embodiments but, on the contrary, the present disclosure is to cover all modifications and alternatives falling within the spirit and scope of the present disclosure.

Relational terms such as first, second, and the like may be used for describing various elements, but the elements should not be limited by the terms. These terms are only used to distinguish one element from another. For example, a first component may be named a second component without departing from the scope of the present disclosure, and the second component may also be similarly named the first component. The term “and/or” means any one or a combination of a plurality of related and described items.

In the present disclosure, “at least one of A and B” may refer to “at least one of A or B” or “at least one of combinations of one or more of A and B”. In addition, “one or more of A and B” may refer to “one or more of A or B” or “one or more of combinations of one or more of A and B”.

When it is mentioned that a certain component is “coupled with” or “connected with” another component, it should be understood that the certain component is directly “coupled with” or “connected with” to the other component or a further component may be disposed therebetween. In contrast, when it is mentioned that a certain component is “directly coupled with” or “directly connected with” another component, it will be understood that a further component is not disposed therebetween.

The terms used in the present disclosure are only used to describe specific exemplary embodiments, and are not intended to limit the present disclosure. The singular expression includes the plural expression unless the context clearly dictates otherwise. In the present disclosure, terms such as ‘comprise’ or ‘have’ are intended to designate that a feature, number, step, operation, component, part, or combination thereof described in the specification exists, but it should be understood that the terms do not preclude existence or addition of one or more features, numbers, steps, operations, components, parts, or combinations thereof.

Unless otherwise defined, all terms (including technical and scientific terms) used herein have the same meaning as commonly understood by one of ordinary skill in the art to which this disclosure belongs. Terms that are generally used and have been in dictionaries should be construed as having meanings matched with contextual meanings in the art. In this description, unless defined clearly, terms are not necessarily construed as having formal meanings.

Hereinafter, exemplary embodiments of the present disclosure will be described in detail with reference to the accompanying drawings. In describing the disclosure, to facilitate the entire understanding of the disclosure, like numbers refer to like elements throughout the description of the figures and the repetitive description thereof will be omitted.

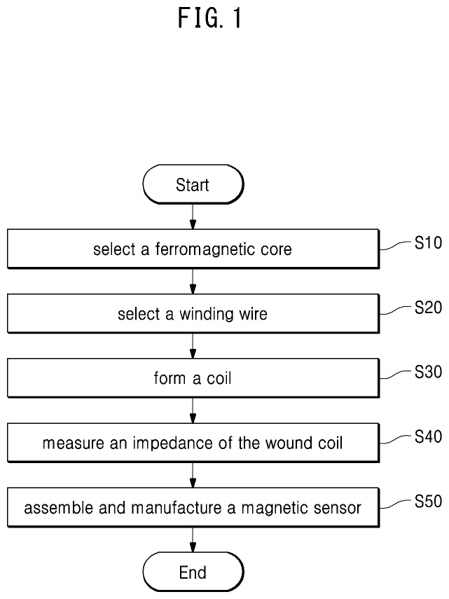

FIG. 1 is a flowchart illustrating a method for manufacturing an RF magnetic sensor according to an exemplary embodiment of the present disclosure.

In step S10, a ferromagnetic core may be selected.

For example, a ferromagnetic core may be selected based on a type and implementation scheme of the RF magnetic sensor. The types of magnetic sensors may include fluxgate sensors, magnetic sensors using a giant magneto-impedance (GMI) scheme, magnetic sensors using a magnetic induction scheme, and magnetic sensors using a magneto-resistance scheme.

For instance, in the case of a magnetic sensor using the GMI scheme, an amorphous wire may be selected as the ferromagnetic core. The amorphous wire may have a high initial permeability u¿ characteristic of 104. In an exemplary embodiment of the present disclosure, an amorphous wire with a diameter in a micrometer range and a length of several tens of millimeters may be used as the ferromagnetic core.

In an exemplary embodiment of the present disclosure, for example, a basic RF magnetic sensor using a single amorphous wire (diameter: 100 μm, length: 85 mm) as a ferromagnetic core and a differential RF magnetic sensor using two amorphous wires as a ferromagnetic core may be configured and manufactured. A multi-core ferromagnetic core may be constructed using multiple amorphous wires, which can enhance the sensitivity and performance of the sensor.

For instance, in the case of an RF magnetic sensor using the magnetic induction scheme, soft magnetic ferrite may be selected as a ferromagnetic core. The soft magnetic ferrite may be, for example, NiZn ferrite, MgZn ferrite, or MnZn ferrite. The shape of the soft magnetic ferrite may include cylindrical or rod shapes. Selecting the soft magnetic ferrite in a cylindrical or rod shape may be advantageous for coil winding.

In this case, soft magnetic ferrite with a high permeability in a range of several tens to hundreds, a diameter of several millimeters, and a length of several tens of millimeters may be selected as the ferromagnetic core. For example, in an exemplary embodiment of the present disclosure, in the case of an RF magnetic sensor using the magnetic induction scheme, the number of ferromagnetic cores (e.g. diameter: 5 mm, length: 35 mm) may be varied as one, two, or four to implement basic, dual, differential, and dual-differential magnetic sensors. Increasing the number of ferromagnetic cores may improve sensor performance.

As described above, the ferromagnetic core may be selected by considering the material and size of the ferromagnetic core according to the type of magnetic sensor. Additionally, the appropriate number of ferromagnetic cores may be selected depending on the implementation scheme of the magnetic sensor.

In step S20, a winding wire for a pickup coil on the ferromagnetic core may be selected. Step S20 may involve selecting a wire to be wound directly on the ferromagnetic core or, if direct winding on the ferromagnetic core is not feasible, selecting a wire to be wound on a non-magnetic insulating tube or bobbin to which the ferromagnetic core is inserted.

In this case, the coil formed on the ferromagnetic core may be referred to as the pickup coil. Coated copper wire or enameled copper wire is commonly used as a wire for the pickup coil. For instance, Self-Bonding Polyurethane Enameled Round Copper Wire (SBUEW) and Heat-Bonding Polyurethane Enameled Round Copper Wire (HBUEW) may be used as pickup coil wires due to their excellent durability and heat resistance.

The diameter of the wire may be an important parameter for selecting the wire for the pickup coil. For example, in the case of a copper wire, the diameter of the wire may be selected to be smaller than a frequency band in use by calculating a skin effect or skin depth of the copper wire. For instance, at a frequency of 20 kHz, the skin depth of the copper wire may be calculated as 0.46 mm. In this case, the diameter of the copper wire may need to be smaller than 0.46 mm. Selecting the diameter of the copper wire as small as possible, such as 0.1 mm, 0.07 mm, or 0.04 mm, may improve the sensitivity and performance of the sensor. That is, as the wire diameter decreases, the resistance of the wire increases, enhancing the sensor's sensitivity and performance. Accordingly, a wire with a diameter smaller than the skin depth at commercial frequencies may be selected.

In an exemplary embodiment of the present disclosure, an SBUEW with a diameter of 0.04 mm may be selected and used as the pickup coil for the RF magnetic sensor.

In step S30, the wire may be wound on the ferromagnetic core to form the pickup coil.

During the wire winding process, the wire may be wound along the length of the ferromagnetic core. In this case, the winding width and the number of turns may significantly affect the sensitivity and performance of the RF magnetic sensor. In a VLF/LF band, the number of wire turns may range from several hundred to several thousand and the wire may be wound in multiple layers. The appropriate number of turns may depend on a frequency to be used. Regarding the coil winding width, a minimum width of several tens of millimeters may be required.

For example, in the case of an RF magnetic sensor using the GMI scheme, the number of wire turns and the winding width may require several hundred turns and a winding width of several tens of millimeters in a single layer. In the case of an RF magnetic sensor using the MI scheme, the number of wire turns and the winding width may require several hundred to several thousand turns and a winding width of several tens of millimeters in multiple layers. In step S30 of the RF magnetic sensor manufacturing process, various numbers of turns and winding widths for the pickup coil may be considered.

In step S40, the impedance of the wound coil may be measured.

Step S40 is a step for selecting the pickup coil with an appropriate number of turns and winding width when various combinations are considered in step S30. In step S40, the impedance of the pickup coil corresponding to the wound coil may be measured to analyze the sensitivity and performance of the magnetic sensor. For example, using an impedance measuring equipment, a DC inductance (L), DC capacitance (C), DC resistance (R), and AC impedance (Z) of the pickup coil may be measured based on the number of turns and winding width. The measured impedance values may vary depending on the number of turns and the winding width of the coil. Greater DC resistance and DC inductance values generally enhance the sensor's sensitivity and performance. Additionally, depending on the coil's number of turns and winding width, the impedance (Z) values at different frequencies may have a self-resonance frequency region. An inductive region corresponding to the left region of the self-resonance frequency needs to be used.

As described above, by analyzing the measured impedance values of the wound coil, the appropriate number of turns and winding width of the pickup coil that improve the sensor's sensitivity and performance may be selected. In an exemplary embodiment of the present disclosure, 750 turns and a 750 mm winding width may be considered for an RF magnetic sensor using the GMI scheme, while 3,000 turns and a 28 mm winding width may be considered for an RF magnetic sensor using the MI scheme.

In step S50, the optimal winding width and number of turns determined through impedance measurement may be used to assemble and manufacture the RF magnetic sensor with the ferromagnetic core wound with the pickup coil.

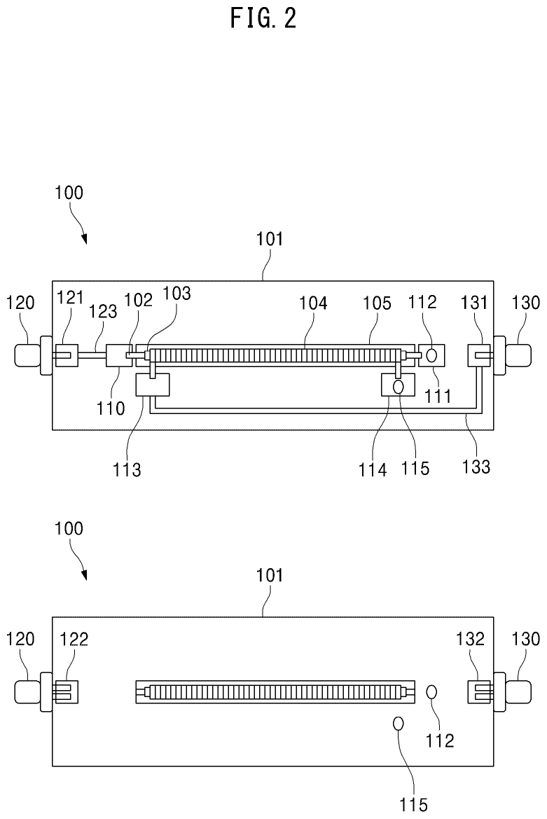

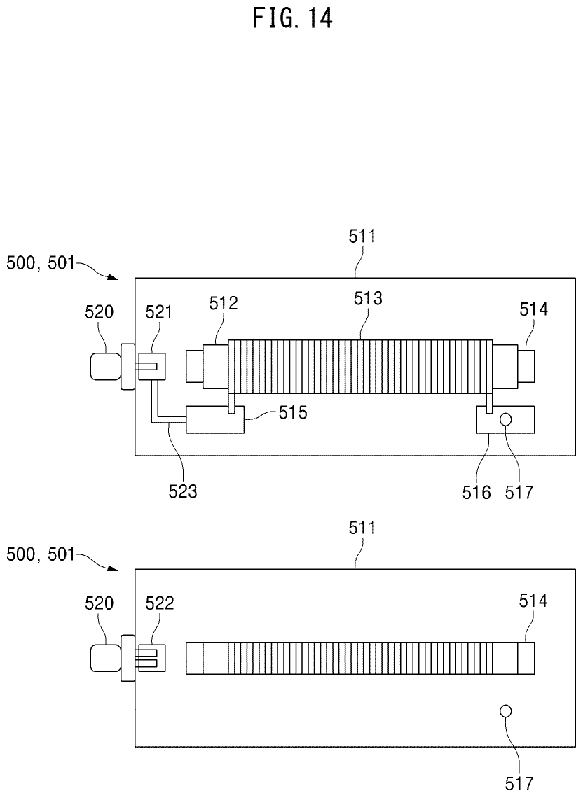

Step S50 is a step of assembling and manufacturing the magnetic sensor using the selected ferromagnetic core and pickup coil. In this case, RF magnetic sensors using the GMI scheme, such as one-axis, two-axis, and three-axis sensors, may be manufactured as illustrated in FIGS. 2 to 5 and FIGS. 8 to 13. For RF magnetic sensors using the MI scheme, one-axis, two-axis, and three-axis sensors may be manufactured as illustrated in FIGS. 14 to 19 and FIGS. 22 to 27.

Hereinafter, methods for mounting a one-axis magnetic sensor using the GMI or MI scheme on a PCB and manufacturing two-axis and three-axis sensors using the one-axis magnetic sensor will be described.

FIG. 2 illustrates both sides of a basic 1-axis magnetic sensor using the GMI scheme according to an exemplary embodiment of the present disclosure.

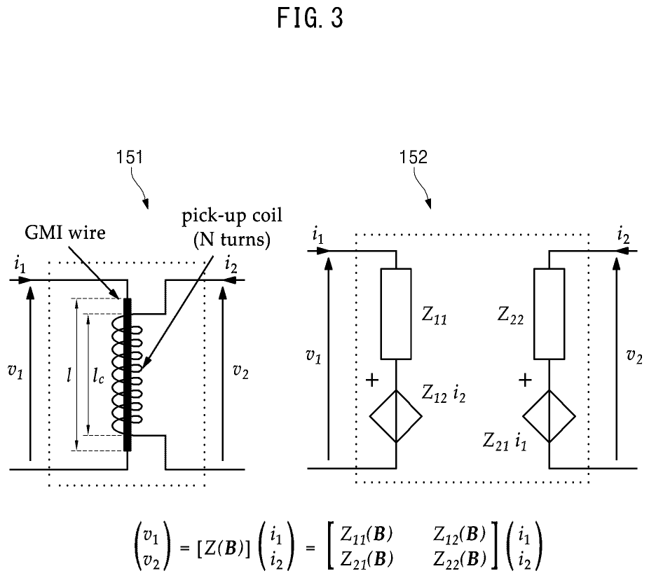

FIG. 3 illustrates an equivalent electrical circuit of the 1-axis magnetic sensor illustrated in FIG. 2.

Hereinafter, FIGS. 2 and 3 will be described together.

A basic 1-axis RF magnetic sensor according to an exemplary embodiment of the present disclosure may be an RF magnetic sensor implemented on a PCB.

In FIG. 2, the top diagram represents a front side of the 1-axis magnetic sensor, and the bottom diagram represents a rear side of the 1-axis magnetic sensor.

The basic RF magnetic sensor 100 applies an alternating current (AC) to the ferromagnetic core 102, magnetizing the core and generating a magnetic field. The magnetic field produced by the ferromagnetic core 102 and an external magnetic field applied along the longitudinal direction of the core 102 are perpendicular to each other.

For example, as shown in a 2-port network 151 and an equivalent electrical circuit 152 of FIG. 3, the basic RF magnetic sensor 100 may apply AC to the ferromagnetic core (GMI wire) 102, magnetizing the ferromagnetic core. When an external magnetic field is applied along the longitudinal direction of the ferromagnetic core 102, a pickup coil 104, wound circumferentially around the ferromagnetic core 102, may output a strength of the external magnetic field as a voltage.

In this case, an impedance, which represents the AC voltage/current ratio (AC resistance) of the pickup coil 104, is shown in FIG. 3. A change of the basic RF magnetic sensor 100, caused by the magnetic field, may be represented by an impedance effect, referred to as a giant magneto-impedance (GMI) effect. Thus, the basic RF magnetic sensor 100 may be referred to as an RF magnetic sensor using the GMI scheme.

The basic RF magnetic sensor 100 has a structure in which AC is applied to the ferromagnetic core 102, and the magnetic field is converted into a voltage in the pickup coil 104, thereby outputting the voltage. In the equivalent electrical circuit 152 of FIG. 3, the impedance for the AC current is a component Z₂₁. The giant magneto-impedance characterized by the component Z₂₁ characterizes an off-diagonal GMI sensor, which may share the same configuration as a fundamental mode fluxgate sensor. Therefore, the RF magnetic sensor in FIG. 2, according to an exemplary embodiment of the present disclosure, may be referred to as a magnetic sensor having the same structure as an off-diagonal GMI sensor and a fundamental mode fluxgate sensor.

Referring to the front side of the basic RF magnetic sensor 100, the ferromagnetic core 102 is inserted into a non-magnetic insulating tube 103, and the pickup coil 104 may be wound circumferentially around the non-magnetic insulating tube 103.

For example, the ferromagnetic core may be made of soft magnetic materials such as cobalt-based or iron-based amorphous metals, permalloy (Ni80%, Fe20%) metals, and the like. In an exemplary embodiment of the present disclosure, the ferromagnetic core 102 may be a cobalt-based amorphous wire with a diameter of several hundred μm and a length of several tens of millimeters.

Both ends of the ferromagnetic core 102, inserted into the non-magnetic insulating tube 103, are arranged in a rectangular open structure 105 at the center of the PCB 101. Core pads 110 and 111 may be located at both ends of the open structure 105. For example, the core pads 110 and 111 and the ferromagnetic core 102 may be bonded through plating.

Meanwhile, it may be challenging to wind the coil directly around the ferromagnetic core 102 with a diameter of several hundred μm. Additionally, during the direct winding process, the ferromagnetic core 102 may break, or its permeability characteristics may change. In such cases, the pickup coil 104 may be formed by winding the wire around the non-magnetic insulating tube 103.

On the front side of the RF magnetic sensor 100, the ferromagnetic core 102 connected to one side of the core pad 110 may be connected to one side 121 of an input terminal 120 through an input signal line 123. The ferromagnetic core 102, connected to a via hole 112 of the core pad 111, may be connected to the ground on the rear side of the RF magnetic sensor 100.

In the one side 121 of the input terminal 120, input conditions for magnetizing the ferromagnetic core 102 are required, and the input conditions may include a frequency and current. Among the input conditions, the frequency may be an AC frequency in a range of several MHz, and the current may include an AC current and a DC current/bias. In an exemplary embodiment of the present disclosure, an AC current and a DC bias mixed at a frequency of 5 MHz may be applied to the one side 121 of the input terminal 120 for magnetizing the ferromagnetic core 102. By additionally applying the DC bias as described above, an effect of reducing magnetic noise in the magnetization process of the ferromagnetic core 102 can be achieved. The other side 131 of the input terminal 120 may be connected to the ground at the rear of the RF magnetic sensor.

The pickup coil 104 is wound circumferentially on the non-magnetic insulating tube 103, and a starting point of the pickup coil 104 may be connected to a coil pad 113 and further connected to one side 131 of an output terminal 130 via an output signal line 133. The ending point of the pickup coil 104 may be connected to a coil pad 114 and further connected to the ground at the rear of the RF magnetic sensor 100 via a via-hole 115. The other side 132 of the output terminal 130 may be connected to the ground at the rear of the RF magnetic sensor 100. For example, the pickup coil 104 and the coil pads 113 and 114 may be joined to each other by a soldering scheme.

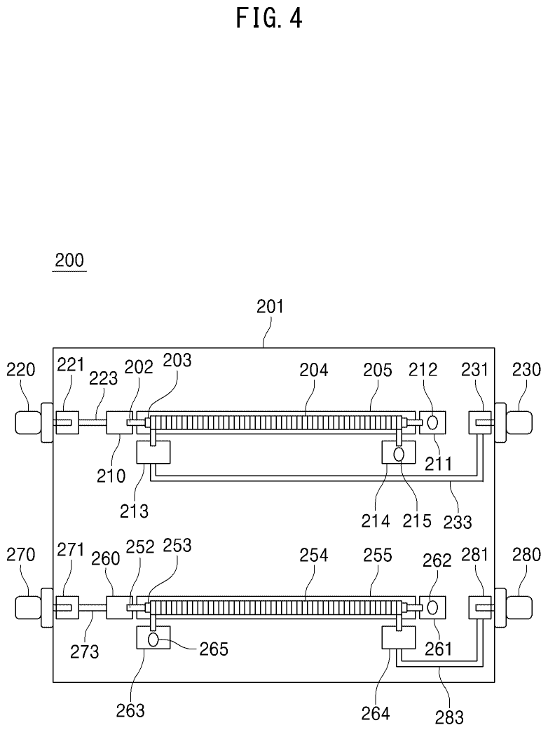

FIG. 4 is a diagram illustrating a differential RF magnetic sensor using the GMI scheme according to an exemplary embodiment of the present disclosure.

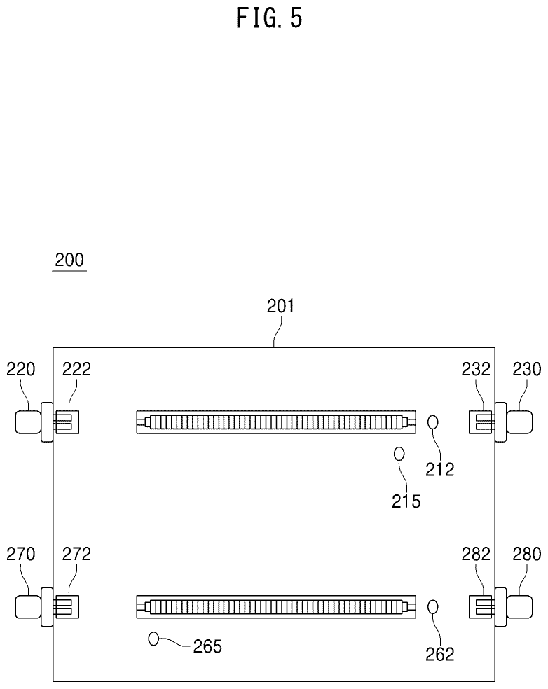

FIG. 5 is another diagram illustrating a differential RF magnetic sensor using the GMI scheme according to an exemplary embodiment of the present disclosure.

Specifically, FIG. 4 illustrates a front side of the differential RF magnetic sensor, and FIG. 5 illustrates a rear side of the differential RF magnetic sensor.

Hereinafter, FIGS. 4 and 5 will be described together.

The RF magnetic sensor shown in FIG. 4 and FIG. 5 is a differential RF magnetic sensor 200 with superior performance compared to the basic RF magnetic sensor 100 shown in FIG. 2 and FIG. 3. The RF magnetic sensor may be configured to increase a transmission distance of magnetic field communication, which is one of the objectives of the present disclosure.

While the basic RF magnetic sensor 100 shown in FIG. 2 and FIG. 3 is composed of one ferromagnetic core 102, one pickup coil 104, one input terminal 120, and one output terminal 130, the differential RF magnetic sensor 200 using the GMI scheme shown in FIG. 4 and FIG. 5 may be composed of two ferromagnetic cores 202 and 252, two pickup coils 204 and 254, two input terminals 220 and 270, and two output terminals 230 and 280.

The connection scheme with the magnetic core in the differential RF magnetic sensor 200 may be the same as the connection scheme with the magnetic core in the basic RF magnetic sensor 100.

The differential RF magnetic sensor 200 may have a configuration where two basic RF magnetic sensors 100 are connected on a single PCB 201.

Among the two ends of the magnetic core 102 of the basic RF magnetic sensor 100, one end may be connected to the input terminal 120, and the other end may be connected to the ground at the rear of the basic RF magnetic sensor 100 via the via-hole 112. The differential RF magnetic sensor 200 may have the same connection scheme.

The first ferromagnetic core 202 of the differential RF magnetic sensor 200 may be connected to a core pad 210 and further connected to one side 221 of the input terminal 220 via an input signal line 223. The other side 222 of the input terminal 220 may be connected to the ground at the rear of the differential RF magnetic sensor 200. The first ferromagnetic core 202 connected to the core pad 211 may be connected to the ground at the rear of the differential RF magnetic sensor 200 via a via-hole 212.

The second ferromagnetic core 252 of the differential RF magnetic sensor 200 may be connected to a core pad 260 and further connected to one side 271 of the input terminal 270 via an input signal line 273. The other side 272 of the input terminal 270 may be connected to the ground at the rear of the differential RF magnetic sensor 200. The second ferromagnetic core 252 connected to a core pad 261 may be connected to the ground at the rear of the differential RF magnetic sensor 200 via a via-hole 262.

On the front side of the differential RF magnetic sensor 200, a non-magnetic insulating tube 203 to which the first ferromagnetic core 202 is inserted and the first pickup coil 204 wound circumferentially on the non-magnetic insulating tube 203 may be arranged within a rectangular open structure 205 of the PCB 201. A starting point of the first pickup coil 204 may be connected to the coil pad 213 and further connected to one side 231 of the output terminal 230 via an output signal line 233. The other side 232 of the output terminal 230 may be connected to the ground at the rear of the differential RF magnetic sensor 200. The ending point of the first pickup coil 204 may be connected to the coil pad 214 and further connected to the ground at the rear of the differential RF magnetic sensor 200 via the via-hole 215. For example, during the aforementioned process, the pickup coil 204 and the coil pads 213 and 214 may be joined by a soldering scheme.

Within a rectangular open structure 255 of the PCB 201, a non-magnetic insulating tube 253 with the second ferromagnetic core 252 inserted and the second pickup coil 254 wound on the non-magnetic insulating tube 253 may be arranged. A starting point of the second pickup coil 254 may be connected to a coil pad 263 and further connected to the ground at the rear of the differential RF magnetic sensor 200 via a via-hole 265. An ending point of the second pickup coil 254 may be connected to a coil pad 264 and further connected to one side 281 of the output terminal 280 via an output signal line 283. The other side 282 of the output terminal 280 may be connected to the ground at the rear of the differential RF magnetic sensor 200. For example, during the aforementioned process, the pickup coil 254 and the coil pads 263 and 264 may be joined by a soldering scheme.

In conclusion, the coil connection schemes of the first pickup coil 204 and the second pickup coil 254 in the differential RF magnetic sensor 200 may differ from each other. As described above, by altering the coil connection schemes of the pickup coils 204 and 254, the differential RF magnetic sensor 200 may sense the same magnetic signal but in opposite current directions, resulting in a voltage output with twice the magnitude. The coil connection structure of the differential RF magnetic sensor 200 in accordance with an exemplary embodiment of the present disclosure can contribute to performance improvement and increase a transmission distance in magnetic field communication.

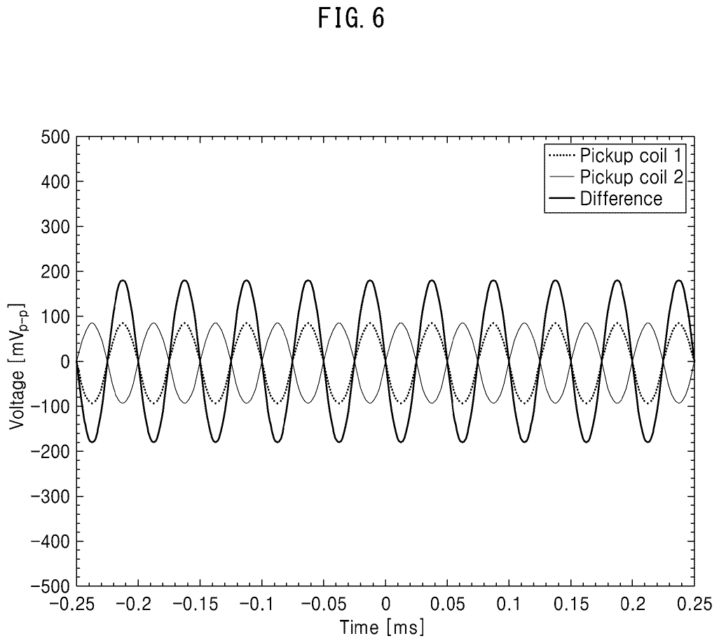

FIG. 6 is a graph illustrating output voltage characteristics, among the performance characteristics of the basic and differential RF magnetic sensors using the GMI scheme according to an exemplary embodiment of the present disclosure.

For example, the graph in FIG. 6 represents the output voltage characteristics measured in the time domain at a frequency of 20 kHz in an exemplary embodiment of the present disclosure. The horizontal axis of the graph represents time in milliseconds (ms), and the vertical axis represents voltage in millivolts peak-to-peak (m Vₚ₋ₚ).

Hereinafter, FIG. 2, FIG. 4, and FIG. 6 will be described together.

The output voltage of the pickup coil 104 in the basic RF magnetic sensor 100 is identical to the output voltage of the first pickup coil 204 in the differential RF magnetic sensor 200. The output voltage of the second pickup coil 254 in the differential RF magnetic sensor 200 exhibits a 180-degree phase difference compared to the first pickup coil 204, as shown in the voltage characteristics. A voltage difference between the two pickup coils 204 and 254 can be observed to be twice the individual voltage difference of each coil relative to the other.

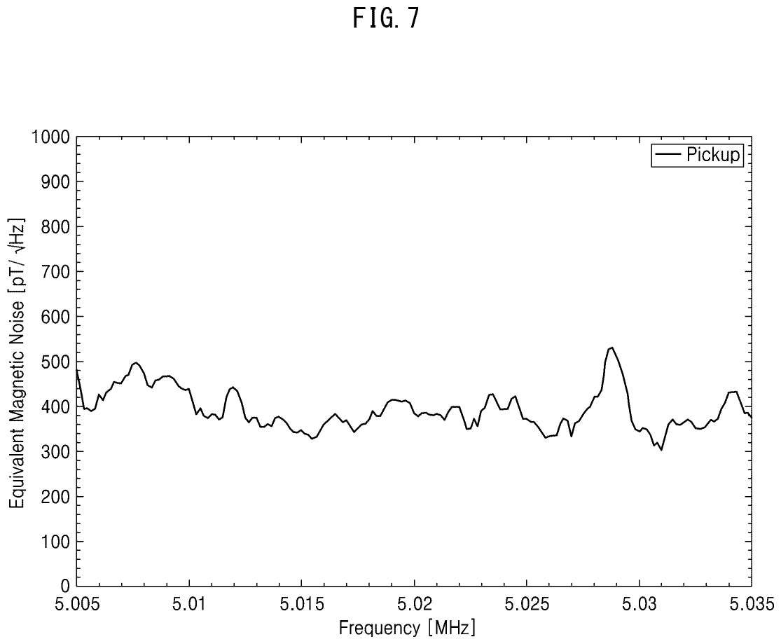

FIG. 7 is a graph illustrating magnetic noise characteristics, among the performance characteristics of the basic and differential RF magnetic sensors using the GMI scheme according to an exemplary embodiment of the present disclosure.

The horizontal axis of the graph represents frequency in megahertz (MHz), and the vertical axis represents equivalent magnetic noise (pT/√Hz).

Referring to the graph in FIG. 7, the two RF magnetic sensors 100 and 200 use the same cobalt-based amorphous wire as the ferromagnetic core, and the magnetic permeabilities of the ferromagnetic cores are identical. Additionally, the same number of pickup coil turns (e.g. 750 turns) is used, and the wire width of the pickup coils is identical (e.g. 750 mm). Since the configurations of the ferromagnetic cores and pickup coils in the RF magnetic sensors 100 and 200 are identical as described above, the magnetic noise characteristics of the basic RF magnetic sensor 100 and the differential RF magnetic sensor 200 may be the same. Here, even though the ferromagnetic cores used in the basic RF magnetic sensor 100 and the differential RF magnetic sensor 200 are the same, the material properties of the ferromagnetic cores may vary depending on the manufacturing process. However, these variations fall within a range of allowable error for material properties. Therefore, the magnetic noise characteristics of the basic RF magnetic sensor 100 and the differential RF magnetic sensor 200 are also almost identical within the margin of error. Due to these characteristics, the magnetic noises of the basic RF magnetic sensor 100 and the differential RF magnetic sensor 200, despite structural differences, are identical because the configurations of the ferromagnetic cores and pickup coils are the same, as shown in the graph of FIG. 7. Examining the graph in FIG. 7 according to an exemplary embodiment of the present disclosure, the RF magnetic sensors 100 and 200 require input conditions (frequency and current) for magnetizing the ferromagnetic cores, and the corresponding frequency and current may be applied. Among the input conditions, the frequency may be an AC frequency in a range of several MHz. In an exemplary embodiment of the present disclosure, for magnetizing the ferromagnetic cores 102, 202, and 252 of the RF magnetic sensors 100 and 200, a frequency of 5 MHz with a mixed AC current and DC bias may be applied. Therefore, the magnetic noise characteristics of the RF magnetic sensors 100 and 200 represent the magnetic noise characteristics for a frequency range corresponding to a mix of the magnetization frequency of 5 MHz and the external magnetic communication signal frequency of 20 kHz (e.g. 5.005 MHz to 5.035 MHz, as shown in FIG. 7). For example, the magnetization frequency of 5 MHz is a frequency required to operate the RF magnetic sensors 100 and 200 and does not correspond to communication signals. Hence, the magnetic noise characteristics for the frequency band, including external magnetic communication signals beyond 5 MHz, are shown in FIG. 7. The frequency of 5.02 MHz on the horizontal axis of FIG. 7 corresponds to the magnetic noise characteristic for 20 kHz communication signals, showing ultra-high sensitivity characteristics of approximately 385 pT/√Hz.

From the output voltage characteristics and the magnetic noise characteristics described above, the RF magnetic sensors 100 and 200 using the GMI scheme in an exemplary embodiment of the present disclosure are shown to have pico-tesla-level ultra-high sensitivity. According to the present disclosure, the differential RF magnetic sensor 200 has twice the output voltage characteristics, a higher signal-to-noise ratio (SNR), and a higher common-mode rejection ratio (CMRR) compared to the basic RF magnetic sensor 100, enabling the detection of weak magnetic signals from long distances. Due to these characteristics, the basic RF magnetic sensor 100 and the differential RF magnetic sensor 200 using the GMI scheme can contribute to extending the communication distance in magnetic field communication to tens of meters or more without relays. Furthermore, the differential RF magnetic sensor 200, with its superior performance characteristics, can contribute more to increasing the communication distance compared to the basic RF magnetic sensor 100.

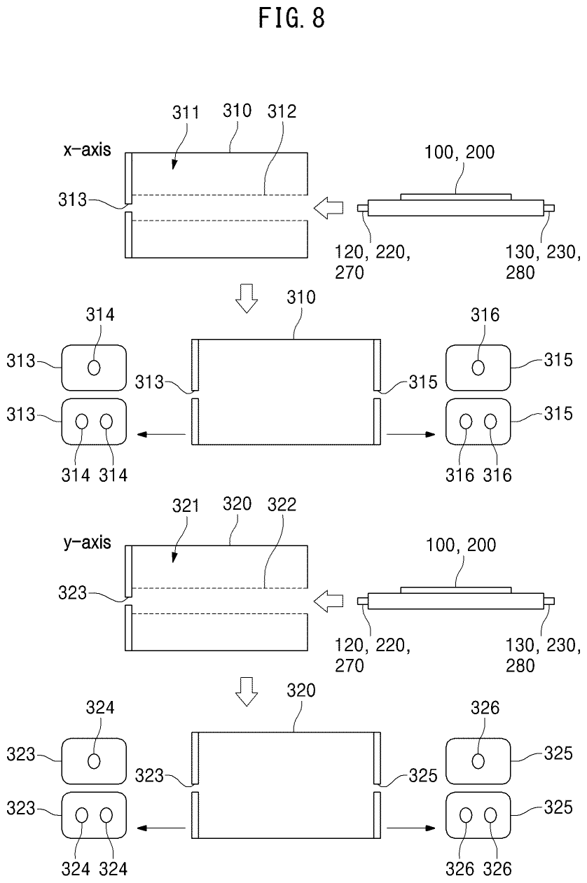

FIG. 8 is a diagram illustrating a manufacturing process of a two-axis RF magnetic sensor using the GMI scheme according to an exemplary embodiment of the present disclosure.

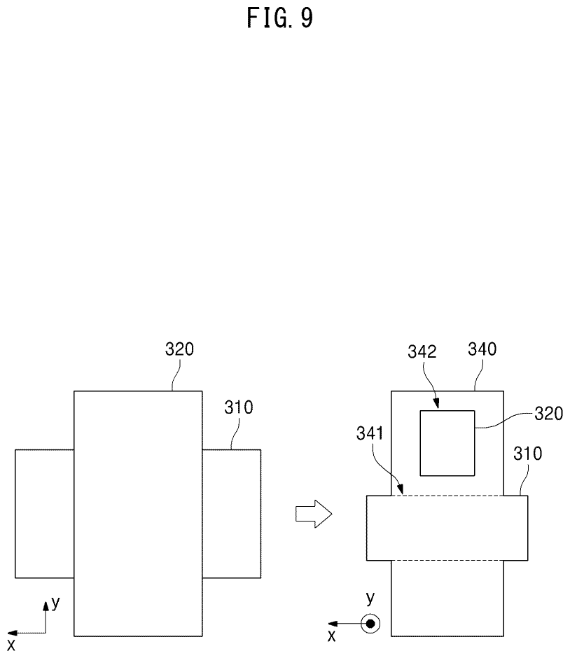

FIG. 9 is another diagram illustrating the manufacturing process of the two-axis RF magnetic sensor using the GMI scheme according to an exemplary embodiment of the present disclosure.

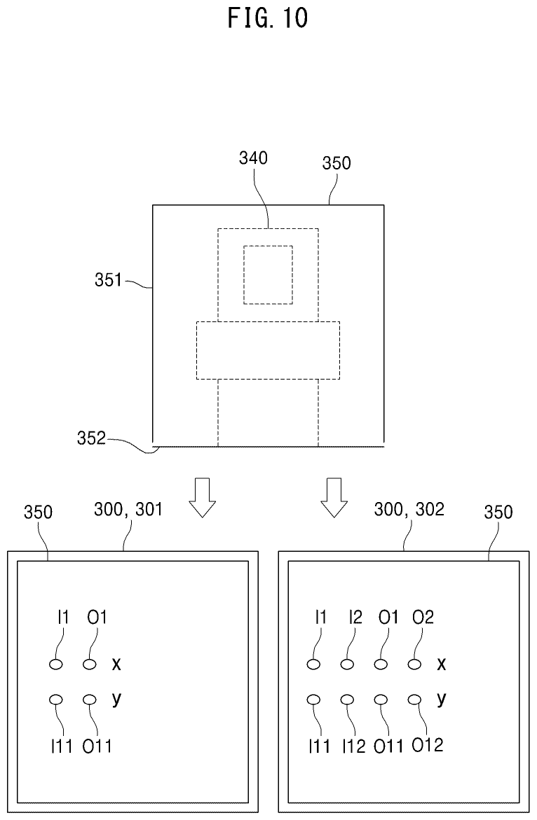

FIG. 10 is a diagram illustrating a housing and input/output ports of the two-axis RF magnetic sensor using the GMI scheme according to an exemplary embodiment of the present disclosure.

Hereinafter, FIG. 8 to FIG. 10 will be described together.

When magnetic field communication is performed in extreme environments (e.g. underwater or underground), RF magnetic sensors for magnetic field communication need to be capable of receiving transmitter communication signals from all directions or from specific directions. To achieve this, it is necessary to have RF magnetic sensors that can be expanded from one-axis sensors to two-axis sensors and three-axis sensors.

To this end, the assembly and manufacturing methods for a two-axis basic RF magnetic sensor 301 and a two-axis differential RF magnetic sensor 302 using the GMI scheme according to an exemplary embodiment of the present disclosure will be described.

The basic RF magnetic sensor 100 and the differential RF magnetic sensor 200 using the GMI scheme may use identical RF magnetic sensors for the x-axis and y-axis to implement and manufacture a two-axis RF magnetic sensor.

The basic or differential RF magnetic sensors 100 and 200 for the x-axis and y-axis may each be inserted into a first inner protective case 310 and a second inner protective case 320, respectively, and combined with the respective inner protective cases 310 and 320. In this case, the first inner protective case 310 and the second inner protective case 320 may be non-magnetic shielding cases.

The non-magnetic shielding cases 310 and 320 may protect the RF magnetic sensors and may serve to combine them with a two-axis fixing jig 340. The non-magnetic shielding cases 310 and 320 may have various shapes, such as rectangular, circular, or elliptical.

When the RF magnetic sensor 100 or 200 is inserted into and combined with the non-magnetic shielding case 310 or 320, the basic or differential RF magnetic sensor 100 or 200 may be inserted into an open structure (i.e. a first insertion hole or a first through-hole) 312 or 322 inside the non-magnetic shielding case 310 or 320. The input ends 120, 220, or 270 of the basic or differential RF magnetic sensor 100 or 200 may be combined with the front cover 313 or 323 of the non-magnetic shielding case 310 or 320.

The interiors of the front covers 313 and 323 of the non-magnetic shielding cases 310 and 320 may include circular open structures (i.e. second through-holes) 314 and 324. The input terminal 120, 220, or 270 of the basic or differential RF magnetic sensor 100 and 200 may be positioned at the open structures 314 or 324 of the front cover 313 or 323 of the non-magnetic shielding case 310 or 320, and the input terminal 120, 220, or 270 may be connected to external RF cables (not shown).

The output terminal 130, 230, or 280 of the basic or differential RF magnetic sensor 100 or 200 may be combined with a rear cover 315 or 325 of the non-magnetic shielding case 310 or 320. The interior of the rear cover 315 or 325 of the non-magnetic shielding case 310 or 320 may include a circular open structure (i.e. third through-hole) 316 or 326. The output terminal 130, 230, or 280 of the basic or differential RF magnetic sensor 100 or 200 may be positioned at the open structure 316 or 326 of the rear cover 315 or 325 of the non-magnetic shielding case 310 or 320, and the output terminal 130, 230, or 280 may be connected to external RF cables (not shown).

Referring to FIG. 9, to implement and manufacture the basic RF magnetic sensor 100 or the differential RF magnetic sensor 200 using the GMI scheme as a two-axis sensor, the x-axis RF magnetic sensor 100 or 200 and the y-axis RF magnetic sensor 100 or 200 need to be arranged perpendicular to each other at a 90-degree angle. The non-magnetic shielding case 310 combined with the basic or differential RF magnetic sensor 100 or 200 may be arranged along the x-axis, and the non-magnetic shielding case 320 combined with the basic or differential RF magnetic sensor 100 or 200 may be arranged along the y-axis, forming a perpendicular configuration.

To maintain the perpendicular orientation of the RF magnetic sensors 100 and 200, the non-magnetic shielding cases 310 and 320 combined with the RF magnetic sensors may be combined with the two-axis fixing jig 340. In this case, the material of the two-axis fixing jig 340 may be an insulating material with non-magnetic properties.

A portion of the interior of the two-axis fixing jig 340 may include open structures 341 and 342 through which the RF magnetic sensors 100 and 200 can penetrate in the x-axis and y-axis directions. That is, the two-axis fixing jig 340 may include fixing jig through-holes 341 and 342. For example, the non-magnetic shielding case 310 combined with the RF magnetic sensor 100 or 200 may penetrate the open structure at the lower part of the two-axis fixing jig 340 (i.e. the first fixing jig through-hole 341) and be coupled along the x-axis direction. The non-magnetic shielding case 320 combined with the RF magnetic sensor 100 or 200 may penetrate the open structure at the upper part of the two-axis fixing jig 340 (i.e. the second fixing jig through-hole 342) and be coupled along the y-axis direction.

Subsequently, referring to FIG. 10, the RF magnetic sensors 100 or 200 combined with the two-axis fixing jig 340 may be combined with a two-axis outer case 350 to complete the two-axis RF magnetic sensor 300.

The two-axis outer case 350 may have shapes such as rectangular, circular, or elliptical. Additionally, the material of the two-axis outer case 350 may be an insulating material with non-magnetic properties.

For example, the two-axis outer case 350 may be composed of two pieces: a bottom surface (i.e. base plate 352) of the lower portion of the two-axis outer case 350 and the upper and side portion (i.e. cover plate 351) of the two-axis outer case 350. For instance, a bottom surface of the lower portion of the two-axis fixing jig 340 may be combined and fixed to the bottom surface 352 of the lower portion of the two-axis outer case 350. The upper and side portion 351 of the two-axis outer case 350 may be combined with the bottom surface 352 of the lower portion of the two-axis outer case 350 in a form that covers the two-axis fixing jig 340.

To manufacture and complete the two-axis basic RF magnetic sensor 301, input ports I1 and I11 and output ports O1 and O11 for the x-axis and y-axis may be located on the front portion of the two-axis outer case 350.

For example, the x-axis input port I1 on the front portion of the two-axis outer case 350 may be connected to the input terminal 120 of the x-axis basic RF magnetic sensor 100 located on the front cover 313 of the non-magnetic shielding case 310 via an RF cable (not shown). The x-axis output port O1 on the front portion of the two-axis outer case 350 may be connected to the output terminal 130 of the x-axis basic RF magnetic sensor 100 located on the rear cover 315 of the non-magnetic shielding case 310 via an RF cable (not shown).

Additionally, the y-axis input port I11 on the front portion of the two-axis outer case 350 may be connected to the input terminal 120 of the y-axis basic RF magnetic sensor 100 located on the front cover 323 of the non-magnetic shielding case 320 via an RF cable (not shown). The y-axis output port O11 on the front portion of the two-axis outer case 350 may be connected to the output terminal 130 of the y-axis basic RF magnetic sensor 100 located on the rear cover 325 of the non-magnetic shielding case 320 via an RF cable (not shown).

Through the process described above, the two-axis basic RF magnetic sensor 301 using the GMI scheme can be manufactured and completed.

In another exemplary embodiment of the present disclosure, to manufacture and complete the two-axis differential RF magnetic sensor 302, input ports I1, I2, I11, and I12 and output ports O1, O2, O11, and O12 for the x-axis and y-axis may be located on the front portion of the two-axis outer case 350.

For example, the x-axis input ports I1, and I2 on the front portion of the two-axis outer case 350 may be connected to the input terminals 220 and 270 of the x-axis differential RF magnetic sensor 200 located on the front cover 313 of the non-magnetic shielding case 310 via RF cables (not shown). The x-axis output ports O1 and O2 on the front portion of the two-axis outer case 350 may be connected to the output terminals 230 and 280 of the x-axis differential RF magnetic sensor 200 located on the rear cover 315 of the non-magnetic shielding case 310 via RF cables (not shown).

Additionally, the y-axis input ports I11 and I12 on the front portion of the two-axis outer case 350 may be connected to the input terminals 220 and 270 of the y-axis differential RF magnetic sensor 200 located on the front cover 323 of the non-magnetic shielding case 320 via RF cables (not shown). The y-axis output ports O11 and O12 on the front portion of the two-axis outer case 350 may be connected to the output terminals 230 and 280 of the y-axis differential RF magnetic sensor 200 located on the rear cover 325 of the non-magnetic shielding case 320 via RF cables (not shown).

Through the process described above, the two-axis differential RF magnetic sensor 302 using the GMI scheme may be manufactured and completed.

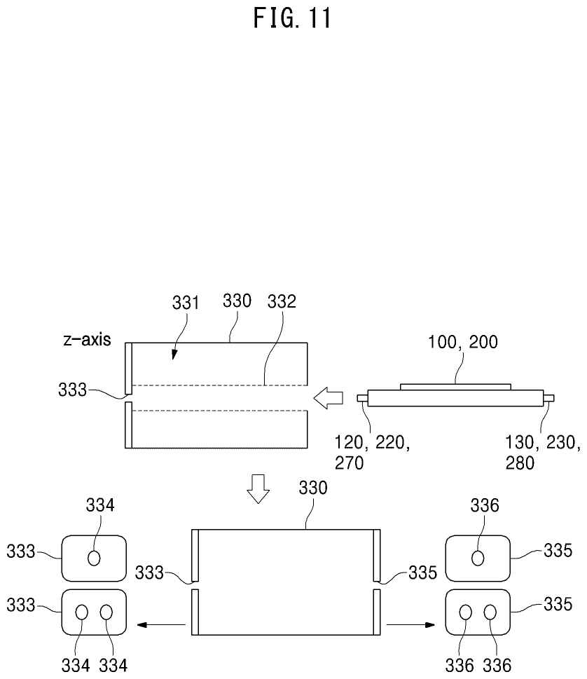

FIG. 11 is a diagram illustrating a manufacturing process of a three-axis RF magnetic sensor using the GMI scheme according to an exemplary embodiment of the present disclosure.

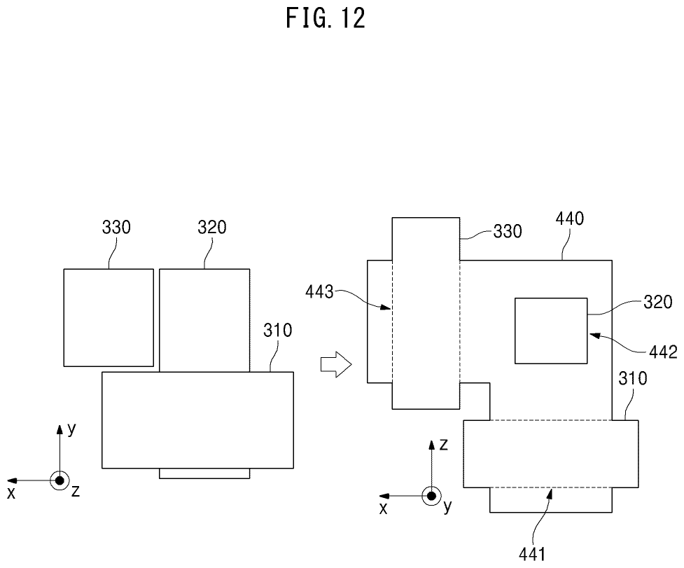

FIG. 12 is another diagram illustrating the manufacturing process of the three-axis RF magnetic sensor using the GMI scheme according to an exemplary embodiment of the present disclosure.

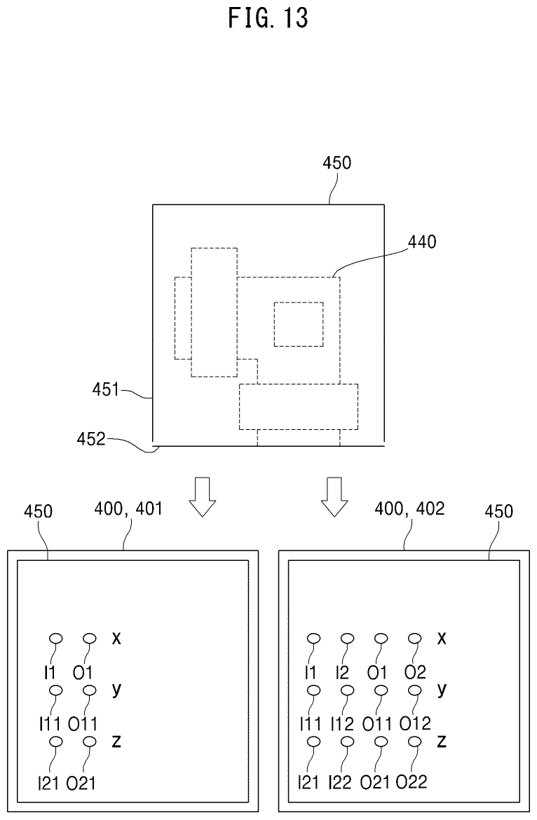

FIG. 13 is a diagram illustrating a housing and input/output ports of the three-axis RF magnetic sensor using the GMI scheme according to an exemplary embodiment of the present disclosure.

Hereinafter, FIG. 8 and FIGS. 11 to 13 will be collectively referred to for describing the assembly and manufacturing methods of the three-axis basic and differential RF magnetic sensors using the GMI scheme.

To implement and manufacture a three-axis basic or differential RF magnetic sensor 400 using the GMI scheme, the same RF magnetic sensors 100 and 200 may be used for the x-axis, y-axis, and z-axis.

In this case, the manufacturing method for the x-axis and y-axis basic or differential RF magnetic sensors required to implement and manufacture the three-axis basic or differential RF magnetic sensor 400 may be the same as described in FIG. 8 for the manufacturing method of the two-axis (x and y-axis) basic or differential RF magnetic sensors.

The manufacturing method for the z-axis basic or differential RF magnetic sensor in the three-axis basic or differential RF magnetic sensor 400 may be as follows.

Referring to FIG. 11, the z-axis basic or differential RF magnetic sensor 100 or 200 may be inserted into a third inner protective case 330, which is a non-magnetic shielding case, and combined with the non-magnetic shielding case 330. The non-magnetic shielding case 330 may serve to protect the RF magnetic sensor and combine it with a three-axis fixing jig 440. The non-magnetic shielding case 330 may have various shapes, such as rectangular, circular, or elliptical.

When the RF magnetic sensor 100 or 200 is inserted into and combined with the non-magnetic shielding case 330, the basic or differential RF magnetic sensor 100 or 200 may be inserted into an open structure (i.e., the first insertion hole or the first through-hole) 332 inside the non-magnetic shielding case 330. The input terminal 120, 220, or 270 of the basic or differential RF magnetic sensor 100 or 200 may be combined with a front cover 333 of the non-magnetic shielding case 330.

The interior of a front cover 333 of the non-magnetic shielding case 330 may include a circular open structure (i.e., the second through-hole) 334. The input terminal 120, 220, or 270 of the basic or differential RF magnetic sensor 100 or 200 may be positioned at the open structure 334 of the front cover 333 of the non-magnetic shielding case 330, and the input terminal 120, 220, or 270 may be connected to external RF cable(s) (not shown).

The output terminal 130, 230, or 280 of the basic or differential RF magnetic sensor 100 or 200 may be combined with a rear cover 335 of the non-magnetic shielding case 330. The interior of the rear cover 335 of the non-magnetic shielding case 330 may include a circular open structure (i.e. the third through-hole) 336. The output terminal 130, 230, or 280 of the basic or differential RF magnetic sensor 100 or 200 may be positioned at the open structure 336 of the rear cover 335 of the non-magnetic shielding case 330, and the output terminal 130, 230, or 280 may be connected to external RF cable(s) (not shown).

Referring to FIG. 12, to implement and manufacture the basic RF magnetic sensor 100 and the differential RF magnetic sensor 200 using the GMI scheme as a three-axis sensor, the x-axis RF magnetic sensor 100 or 200, the y-axis RF magnetic sensor 100 or 200, and the z-axis RF magnetic sensor 100 or 200 need to be arranged perpendicular to each other at 90-degree angles. The non-magnetic shielding case 310 combined with the basic or differential RF magnetic sensor 100 or 200 may be arranged along the x-axis, and the non-magnetic shielding case 320 combined with the basic or differential RF magnetic sensor 100 or 200 may be arranged along the y-axis. Additionally, the non-magnetic shielding case 330 combined with the basic or differential RF magnetic sensor 100 or 200 may be arranged along the z-axis. As described above, by arranging the non-magnetic shielding cases combined with the RF magnetic sensors in the x, y, and z-axis directions, the RF magnetic sensors can be configured to be perpendicular to each other.

The RF magnetic sensors 100 and 200 may be combined with a three-axis fixing jig 440 via the non-magnetic protective cases 310, 320 and 330 associated with the RF magnetic sensors, ensuring that the RF magnetic sensors maintain a vertical orientation. The material of the three-axis fixing jig 440 may be an insulating material made of non-magnetic material.

A portion of the interior of the three-axis fixing jig 440 may have open structures 441, 442, and 443 allowing the RF magnetic sensors 100 and 200 to penetrate in the x-axis, y-axis, and z-axis directions. Specifically, through-holes 441, 442, and 443 may be formed in the three-axis fixing jig 440. For example, the non-magnetic case 310 combined with the RF magnetic sensor 100 or 200 may penetrate the open structure at the bottom of the three-axis fixing jig (i.e. the first fixing jig through-hole 441) and be coupled in the x-axis direction. Similarly, the non-magnetic case 320 combined with the RF magnetic sensor 100 or 200 may penetrate the open structure at the top of the three-axis fixing jig (i.e. the second fixing jig through-hole 442) and be coupled in the y-axis direction. The non-magnetic case 330 combined with the RF magnetic sensor 100 or 200 may penetrate the open structure on the upper-left side of the three-axis fixing jig (i.e. the third fixing jig through-hole 443) and be coupled in the z-axis direction.

Referring to FIG. 13, the RF magnetic sensors coupled to the three-axis fixing jig 440 may then be assembled into a three-axis outer case 450 to complete the three-axis RF magnetic sensor 400.

The shape of the three-axis outer case 450 may be rectangular, circular, elliptical, or other forms. The material of the three-axis outer case 450 may also be an insulating material made of non-magnetic material.

For example, the three-axis outer case 450 may be composed of two pieces: the lower surface of the bottom portion of the three-axis outer case 450 (i.e. the bottom plate 452) and the upper and side portion of the three-axis outer case 450 (i.e. the cover plate 451). The lower surface of the three-axis fixing jig 440 may be fixedly combined with the lower surface of the bottom portion 452 of the three-axis outer case 450. The upper and side portion 451 of the three-axis outer case 450 may then be assembled to cover the three-axis fixing jig 440, completing the structure.

To manufacture and complete the three-axis basic RF magnetic sensor 401, input ports I1, I11, and I21 and output ports O1, O11, and O21 for the x-axis, y-axis, and z-axis may be positioned on the front side of the three-axis outer case 450.

For instance, the input terminal 120 of the x-axis basic RF magnetic sensor 100 located on the front cover 313 of the non-magnetic protective case 310 may be connected to the x-axis input port I1 on the front side of the three-axis outer case 450 via an RF cable (not shown). The output terminal 130 of the x-axis basic RF magnetic sensor 100 located on the rear cover 315 of the non-magnetic protective case 310 may be connected to the x-axis output port O1 on the front side of the three-axis outer case 450 via an RF cable (not shown).

Similarly, the input terminal 120 of the y-axis basic RF magnetic sensor 100 located on the front cover 323 of the non-magnetic protective case 320 may be connected to the y-axis input port I11 on the front side of the three-axis outer case 450 via an RF cable (not shown). The output terminal 130 of the y-axis basic RF magnetic sensor 100 located on the rear cover 325 of the non-magnetic protective case 320 may be connected to the y-axis output port O11 on the front side of the three-axis outer case 450 via an RF cable (not shown).

The input terminal 120 of the z-axis basic RF magnetic sensor 100 located on the front cover 333 of the non-magnetic protective case 330 may be connected to the z-axis input port I21 on the front side of the three-axis outer case 450 via an RF cable (not shown). The output terminal 130 of the z-axis basic RF magnetic sensor 100 located on the rear cover 335 of the non-magnetic protective case 330 may be connected to the z-axis output port O21 on the front side of the three-axis outer case 450 via an RF cable (not shown).

Through the aforementioned process, the three-axis basic RF magnetic sensor 401 based on the GMI scheme can be manufactured and completed.

In another exemplary embodiment of the present disclosure, to manufacture and complete the three-axis differential RF magnetic sensor 402, input ports I1, I2, I11, I12, I21, and I22 and output ports O1, O2, O11, O12, O21, and O22 for the x-axis, y-axis, and z-axis may be positioned on the front side of the three-axis outer case 450.

For example, the x-axis input ports I1 and I2 on the front side of the three-axis outer case 450 may be connected via RF cables (not shown) to the input terminal 220 and 270) of the x-axis differential RF magnetic sensor 200 located on the front cover 313 of the non-magnetic protective case 310. Similarly, the x-axis output ports O1 and O2 on the front side of the three-axis outer case 450 may be connected via RF cables (not shown) to the output terminals 230 and 280 of the x-axis differential RF magnetic sensor 200 located on the rear cover 313 of the non-magnetic protective case 310.

Additionally, the y-axis input ports I11 and I12 on the front side of the three-axis outer case 450 may be connected via RF cables (not shown) to the input terminals 220 and 270 of the y-axis differential RF magnetic sensor 200 located on the front cover 323 of the non-magnetic protective case 320. The y-axis output ports O11 and O12 on the front side of the three-axis outer case 450 may be connected via RF cables (not shown) to the output terminals 230 and 280 of the y-axis differential RF magnetic sensor 200 located on the rear cover 325 of the non-magnetic protective case 320.

The z-axis input ports I21 and I22 on the front side of the three-axis outer case 450 may be connected via RF cables (not shown) to the input terminals 220 and 270 of the z-axis differential RF magnetic sensor 200 located on the front cover 333 of the non-magnetic protective case 330. The z-axis output ports O21 and O22 on the front side of the three-axis outer case 450 may be connected via RF cables (not shown) to the output terminals 230 and 280 of the z-axis differential RF magnetic sensor 200 located on the rear cover 335 of the non-magnetic protective case 330.

Through the aforementioned process, the three-axis differential RF magnetic sensor 402 based on the GMI scheme can be manufactured and completed.

FIG. 14 illustrates both sides of a basic single-axis magnetic sensor based on the MI scheme according to an exemplary embodiment of the present disclosure.

In FIG. 14, the upper diagram shows a front side of a single-axis magnetic sensor 500 or 501 based on the MI scheme, while the lower diagram shows a rear side of the single-axis magnetic sensor 500 or 501 based on the same scheme.

In an exemplary embodiment of the present disclosure, the RF magnetic sensor 500 or 501 based on the MI scheme may be an RF magnetic sensor implemented on a PCB 511.

Hereinafter, the assembly and manufacturing process of the RF magnetic sensor 501 will be described.

For example, when an external magnetic field is applied along the longitudinal direction of a ferromagnetic core 512 of the RF magnetic sensor 501 based on the MI scheme, the ferromagnetic core 512 may become magnetized, and a pickup coil 513 wound around the ferromagnetic core 512 converts the magnetic field generated during magnetization into a voltage output.

The ferromagnetic core 512 of the RF magnetic sensor 501 based on the MI scheme may be made of Ni—Zn ferrite, Mg—Zn ferrite, or Mn—Zn ferrite, and it may have a relative permeability ranging from several tens to several hundreds. The ferrite may have a diameter of a few millimeters and a length of several tens of millimeters.

The RF magnetic sensor 501 may have the pickup coil 513 directly multilayer-wound around the cylindrical ferromagnetic core 512. The ferromagnetic core 512 with the wound pickup coil 513 is positioned at the center of a rectangular open structure 514 on the PCB 511. The pickup coil 513 and the surrounding rectangular open structure 514 may be bonded and secured using adhesives such as glue or silicone.

At the bottom of the rectangular open structure 514, coil pads 515 and 516 are positioned. A starting point of the pickup coil 513 is connected to the coil pad 515 and is further connected to one side 521 of an output terminal 520 via an output signal line 523. An ending point of the pickup coil 513 is connected to the coil pad 516 and is further connected to the ground on the rear side of the RF magnetic sensor 501 via a via hole 517. The other side 522 of the output terminal 520 is connected to the ground on the rear side of the RF magnetic sensor 501. For example, the pickup coil 513 and the coil pads 515, 516 may be soldered together.

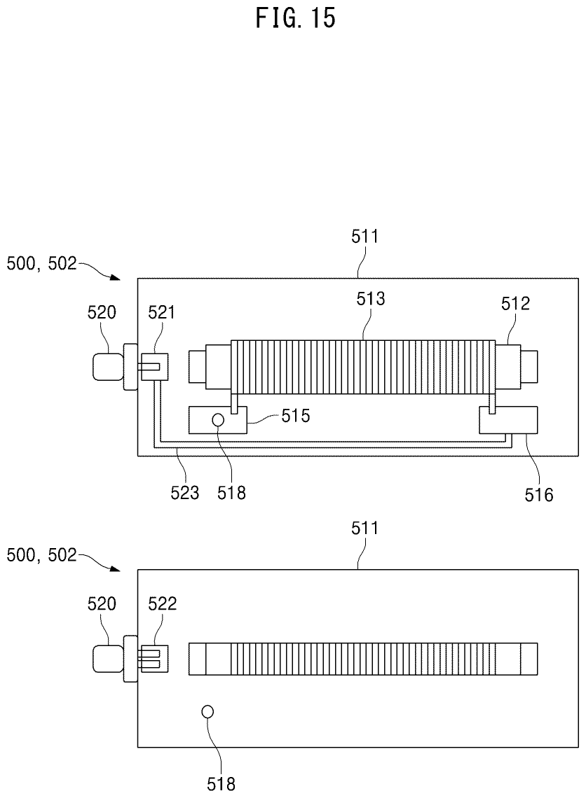

FIG. 15 illustrates both sides of a basic single-axis magnetic sensor based on the MI scheme according to another exemplary embodiment of the present disclosure.

A difference between the basic RF magnetic sensors 500 or 501 in FIG. 14 and the basic RF magnetic sensor 500 or 502 in FIG. 15 lies in the connection of the pickup coil.

In the RF magnetic sensor 502, a starting point of the pickup coil 513 is connected to the coil pad 515 and further connected to the ground on the rear side of the RF magnetic sensor 502 via a via hole 518. The ending point of the pickup coil 513 is connected to the coil pad 516 and further connected to one side 521 of the output end 520 via an output signal line 523. The other side 522 of the output terminal 520 is connected to the ground on the rear side of the RF magnetic sensor 502. For example, the pickup coil 513 and the coil pads 515, 516 may be soldered together.

Since the connection of the pickup coil 513 differs between the RF magnetic sensor 501 in FIG. 14 and the RF magnetic sensor 502 in FIG. 15, the direction of current is reversed, resulting in an identical output voltage magnitude but a 180-degree phase difference. For example, the magnitude and phase difference of the output voltage may be similar to the output voltage characteristics shown in FIG. 6. The output voltage characteristics of the RF magnetic sensor 501 may correspond to the output voltage characteristics labeled ‘Pickup coil 1’ in FIG. 6, and the output voltage characteristics of the RF magnetic sensor 502 may correspond to the output voltage characteristics labeled ‘Pickup coil 2’ in FIG. 6.

Meanwhile, one objective of the present disclosure is to provide a dual RF magnetic sensor 600 based on the magnetic induction scheme with a configuration for increasing a transmission range of magnetic field communication.

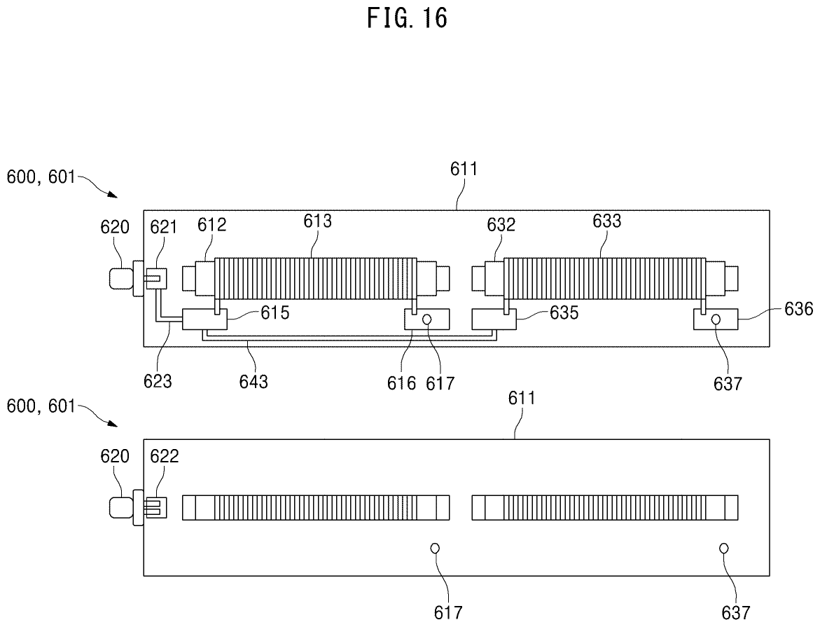

FIG. 16 illustrates both sides of a dual RF magnetic sensor based on the MI scheme according to an exemplary embodiment of the present disclosure.

In FIG. 16, the upper diagram shows a front side of the dual RF magnetic sensor 600, 601 based on the MI scheme, while the lower diagram shows a rear side of the dual RF magnetic sensor 600, 601 based on the same scheme.

The dual RF magnetic sensor 601 based on the MI scheme in FIG. 16 is formed by connecting two identical configurations of the basic RF magnetic sensor 501 from FIG. 14 on a single substrate 611.

The output terminal 620 of the dual RF magnetic sensor 601 may be configured as a single terminal. In the dual RF magnetic sensor 601, the starting points of the first pickup coil 613 and the second pickup coil 633 are connected to the coil pads 615 and 635, respectively, and further connected to one side 621 of the output terminal 620 via output signal lines 623 and 643. The ending points of the first pickup coil 613 and the second pickup coil 633 are connected to the coil pads 616 and 636, respectively, and further connected to the ground on the rear side of the dual RF magnetic sensor 601 through via holes 617 and 637. The other side 622 of the output terminal 620 is connected to the ground on the rear side of the dual RF magnetic sensor 601. For example, the pickup coils 613 and 633 and the coil pads 615, 616, 635 and 636 may be soldered together.

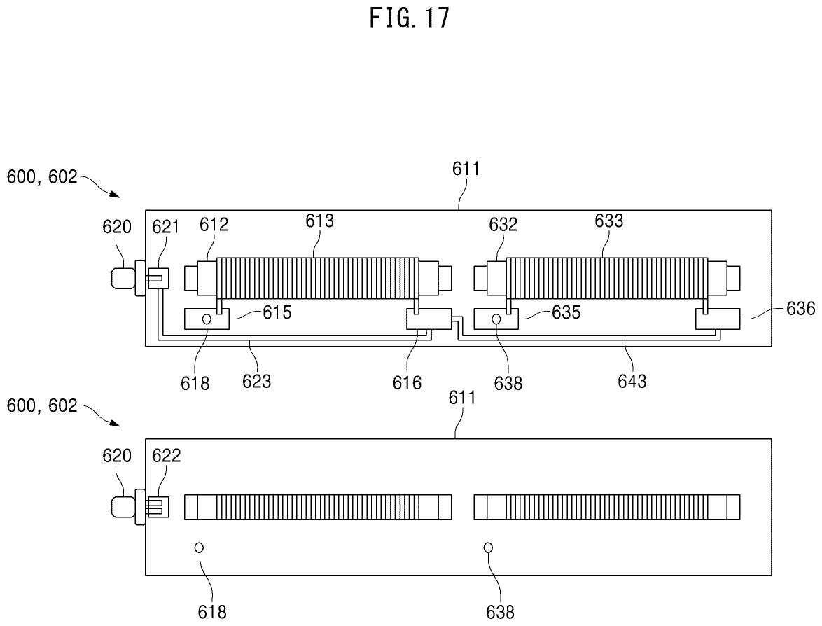

FIG. 17 illustrates both sides of a dual RF magnetic sensor using the MI scheme according to another exemplary embodiment of the present disclosure.

The upper diagram of FIG. 17 represents a front side of the dual RF magnetic sensor 600, 602 using the MI scheme, and the lower diagram thereof represents a rear side of the dual RF magnetic sensor 600, 602 using the MI scheme.

The dual RF magnetic sensor 602 using the MI scheme in FIG. 17 is formed by connecting two basic RF magnetic sensors 502 in FIG. 15 with the same structure.

The output terminal 620 of the dual RF magnetic sensor 602 may be configured as a single terminal. In the dual RF magnetic sensor 602, the starting points of a first pickup coil 613 and a second pickup coil 633 are connected to coil pads 615 and 635 and may be connected to the ground on the rear side of the dual RF magnetic sensor 602 through via holes 618 and 638. The ending points of the first pickup coil 613 and the second pickup coil 633 in the dual RF magnetic sensor 602 are connected to the coil pads 616 and 636 and may be connected to one side 621 of the output terminal 620 through output signal lines 623 and 643. The other side 622 of the output terminal 620 may be connected to the ground on the rear side of the dual RF magnetic sensor 602. For example, the pickup coils 613 and 633 and the coil pads 615, 616, 635, and 636 may be joined together using a soldering scheme.

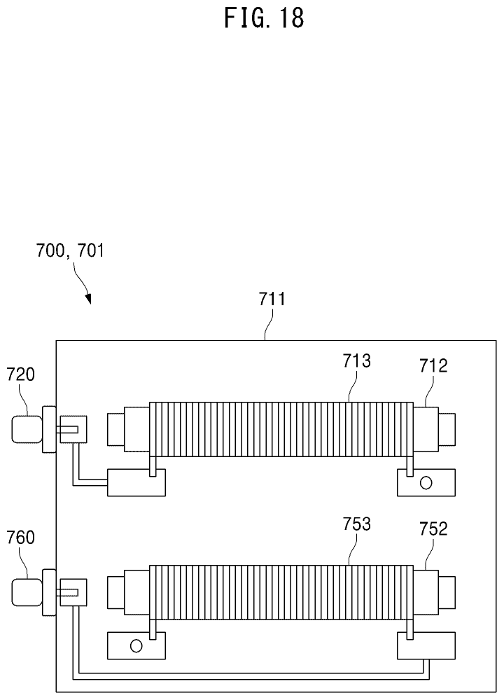

FIG. 18 is a diagram illustrating a differential RF magnetic sensor using the MI scheme according to an exemplary embodiment of the present disclosure.

The differential RF magnetic sensor 700 or 701 using the MI scheme may be implemented as an RF magnetic sensor based on a PCB 711.

The differential RF magnetic sensor 701 in FIG. 18 is formed by combining the basic RF magnetic sensor 501 in FIG. 14 and the basic RF magnetic sensor 502 in FIG. 15 on a single substrate 711. In other words, while the basic RF magnetic sensors 501 and 502 are implemented on the respective PCBs 511, requiring two PCBs, the differential RF magnetic sensor 701 may be implemented on a single PCB 711, having a configuration with two output terminals 720 and 760, which may be manufactured accordingly.

The differential RF magnetic sensor 701 may include two output terminals 720 and 760 corresponding to the output terminal 520 of the basic RF magnetic sensor 501 and the output terminal 520 of the basic RF magnetic sensor 502. The differential RF magnetic sensor 701 may sense the same signal at the two output terminals 720 and 760 but generate a differential output (inverted output and non-inverted output), doubling a voltage output and thereby contributing to performance improvement and increasing a transmission distance in magnetic field communication.

The manufacturing method for the differential RF magnetic sensor 701 may be derived by inferring from the manufacturing method for the basic RF magnetic sensors 501 and 502 shown in FIG. 14 and FIG. 15, and a detailed description on the manufacturing method is omitted.

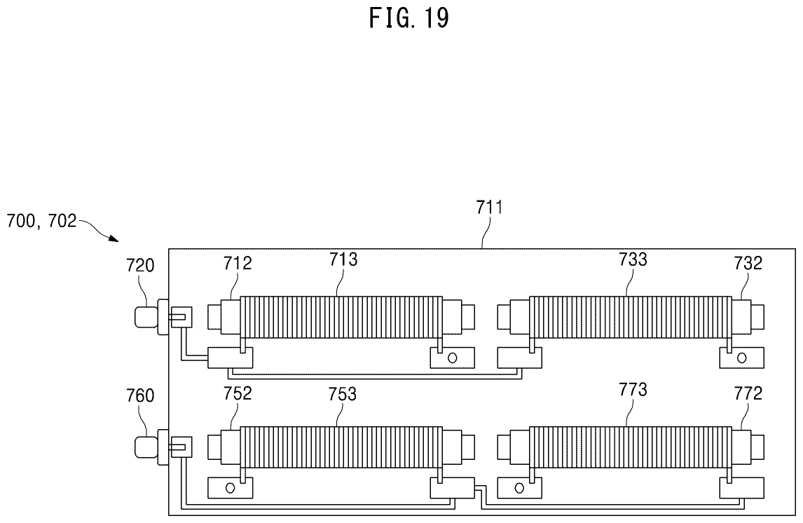

FIG. 19 is a diagram illustrating a dual differential RF magnetic sensor using the MI scheme according to another exemplary embodiment of the present disclosure.

The dual differential RF magnetic sensor 700 or 702 using the MI scheme may be implemented as an RF magnetic sensor based on a PCB 711.

The dual differential RF magnetic sensor 702 in FIG. 19 is formed by combining the dual RF magnetic sensor 601 in FIG. 16 and the dual RF magnetic sensor 602 in FIG. 17 on a single substrate 711. In other words, while the dual RF magnetic sensors 601 and 602 are implemented on the respective PCBs 611, requiring two PCBs, the dual differential RF magnetic sensor 702 may be implemented on a single PCB 711, having a configuration with two output terminals 720 and 760, which may be manufactured accordingly.

The dual differential RF magnetic sensor 702 may include two output terminals 720 and 760 corresponding to the output terminals 620 of the dual RF magnetic sensors 601 and 602. The dual differential RF magnetic sensor 702 may sense the same signal at the two output terminals 720 and 760 but generate a differential output, doubling a voltage output and thereby contributing to performance improvement and increasing a transmission distance in magnetic field communication.

The manufacturing method for the dual differential RF magnetic sensor 702 may be derived by inferring from the manufacturing method for the dual RF magnetic sensors 601 and 602 shown in FIG. 16 and FIG. 17, and a detailed description on the manufacturing method is omitted.

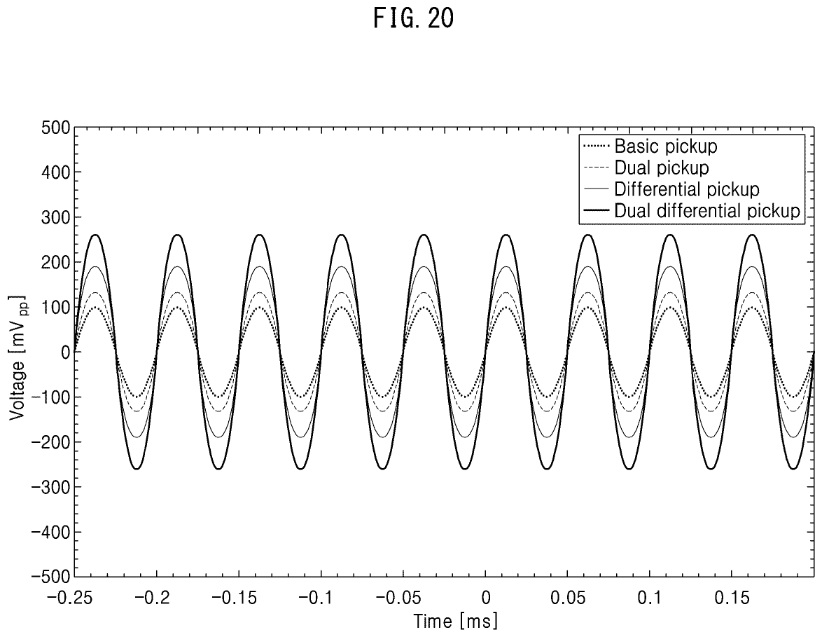

FIG. 20 is a graph illustrating output voltage characteristics, among the performance characteristics, of RF magnetic sensors using the MI scheme according to an exemplary embodiment of the present disclosure.

Specifically, FIG. 20 includes a graph for the basic RF magnetic sensor 501 (i.e. basic pickup), a graph for the dual RF magnetic sensor 601 (i.e. dual pickup), a graph for the differential RF magnetic sensor 701 (i.e. differential pickup), and a graph for the dual differential RF magnetic sensor 702 (i.e. dual differential pickup).

The horizontal axis of each graph represents time in milliseconds (ms), and the vertical axis represents voltage in millivolts peak-to-peak (m Vₚₚ).

Comparing the voltage characteristics of the respective graphs, the magnitude of the output voltage characteristics appears in the order: basic pickup<dual pickup<differential pickup<dual differential pickup. From the graph results in FIG. 20, it is evident that the output voltage characteristics of the dual differential RF magnetic sensor 702 are the most superior.

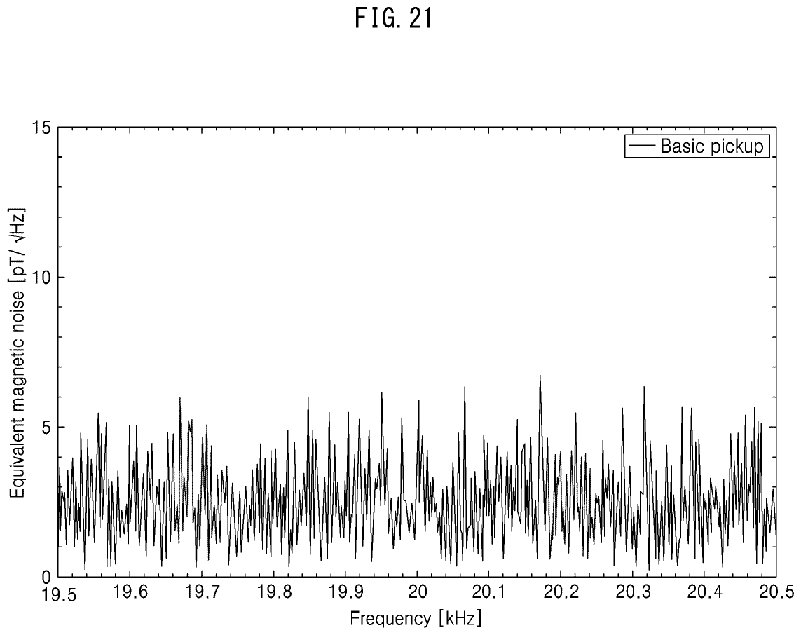

FIG. 21 is a graph illustrating magnetic noise characteristics, among the performance characteristics, of RF magnetic sensors using the MI scheme according to an exemplary embodiment of the present disclosure.

The horizontal axis of the graph (i.e. basic pickup) for the RF magnetic sensors 501, 502, 601, 602, 701, and 702 represents frequency in kilohertz (kHz), and the vertical axis represents equivalent magnetic noise in pico-tesla per square root hertz (pT/√Hz).

The magnetic noise characteristics of the RF magnetic sensors 501, 502, 601, 602, 701, and 702 in the present disclosure may be identical. Although the structures of the RF magnetic sensors 501, 502, 601, 602, 701, and 702 differ, the same ferromagnetic core is used, and wire widths and the number of turns of the pickup coils are identical, leading to identical magnetic noise characteristics. Although the material characteristics of the ferromagnetic cores may vary during the manufacturing processes, the material characteristics do not change beyond a margin of error, allowing the ferromagnetic core to be considered to have nearly identical material properties. Accordingly, the magnetic noise characteristics of the RF magnetic sensors 501, 502, 601, 602, 701, and 702 may be regarded as identical, and the magnetic noise characteristics of the RF magnetic sensors 502, 601, 602, 701, and 702 are omitted (not shown) in FIG. 21. Since proving the ultra-high sensitivity characteristics of the RF magnetic sensors 501, 502, 601, 602, 701, and 702 is important, the magnetic noise characteristic graph (i.e. basic pickup) corresponding to the basic RF magnetic sensor 501 is shown in FIG. 21. Experimental results show that an ultra-high sensitivity characteristic of approximately 5 pT/√Hz was observed at 20 KHz.

From the output voltage characteristics and magnetic noise characteristics in FIG. 20 and FIG. 21, it is evident that the RF magnetic sensors 501, 502, 601, 602, 701, and 702 proposed in the present disclosure exhibit ultra-high sensitivity characteristics at the pico-Tesla level. The dual differential RF magnetic sensor 702, in particular, exhibits the most superior output voltage characteristics, a high signal-to-noise ratio (SNR), and a high common-mode rejection ratio (CMRR), enabling the detection of weak magnetic signals over long distances. Accordingly, the dual differential RF magnetic sensor 702 may contribute to increasing a communication range of magnetic field communication to several hundred meters or more without requiring a relay.

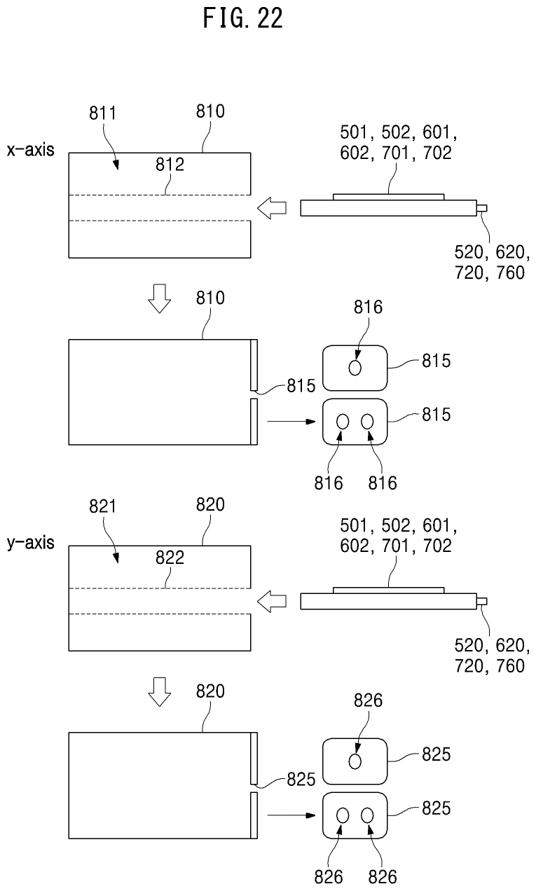

FIG. 22 is a diagram illustrating a manufacturing process of a two-axis RF magnetic sensor using the MI scheme according to an exemplary embodiment of the present disclosure.

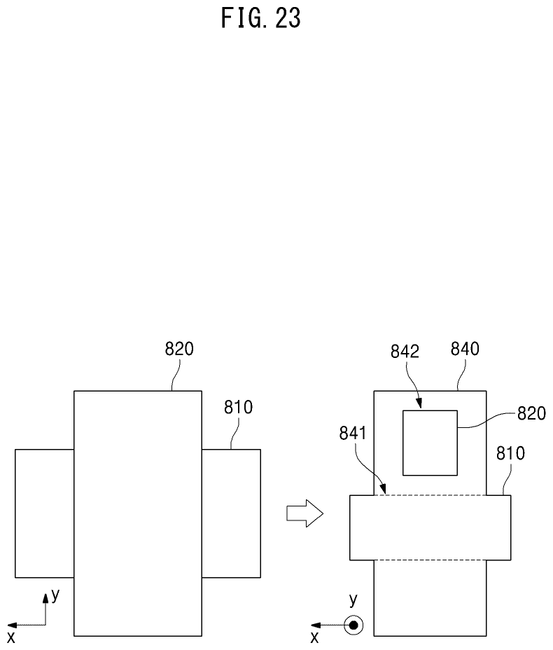

FIG. 23 is another diagram illustrating the manufacturing process of the two-axis RF magnetic sensor using the MI scheme according to an exemplary embodiment of the present disclosure.

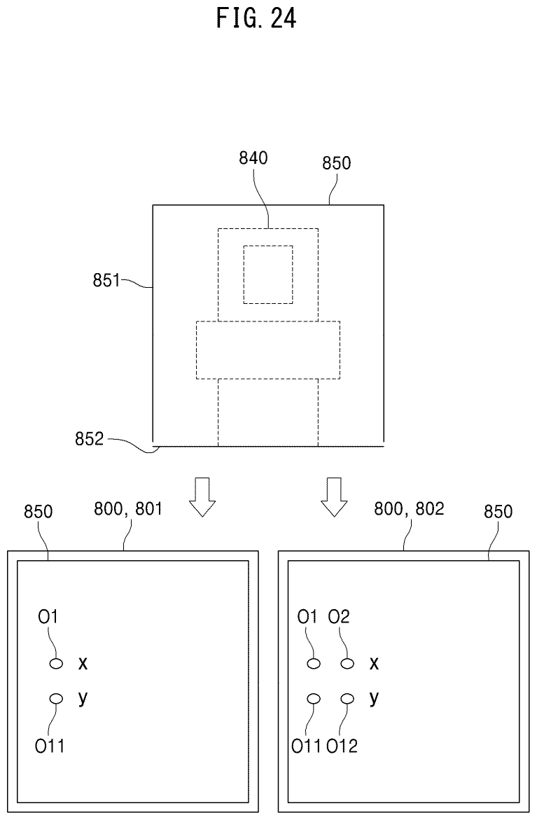

FIG. 24 is a diagram illustrating a housing and input/output ports of the two-axis RF magnetic sensor using the MI scheme according to an exemplary embodiment of the present disclosure.

Hereinafter, FIGS. 22 through 24 will be described together.

To manufacture a two-axis RF magnetic sensor 801 or 802 using the MI scheme, the same RF magnetic sensors 501, 502, 601, 602, 701, and 702 may be used for both the x-axis and y-axis. The RF magnetic sensors 501, 502, 601, 602, 701, and 702 for the x-axis and y-axis may be inserted into a first inner protective case 810 and a second inner protective case 820, respectively, and combined with the corresponding inner protective case. In this case, the first inner protective case 810 and the second inner protective case 820 may be non-magnetic protective cases.

The non-magnetic protective cases 810 and 820 may serve to protect the RF magnetic sensors and may be combined with a two-axis fixing jig 840. The shapes of the non-magnetic protective cases 810 and 820 may be rectangular, circular, elliptical, or other shapes.

When the RF magnetic sensors 501, 502, 601, 602, 701, and 702 are inserted into and combined with the non-magnetic protective cases 810 and 820, the RF magnetic sensors 501, 502, 601, 602, 701, and 702 may be inserted into open internal structures (i.e. first insertion hole or first through-hole) 812 and 822 of the non-magnetic protective cases 810 and 820. The output terminals 520, 620, 720, and 760 of the RF magnetic sensors 501, 502, 601, 602, 701, and 702 may be coupled to the rear covers 815 and 825 of the non-magnetic protective cases 810 and 820.

The internal structure of the rear covers 815 and 825 of the non-magnetic protective cases 810 and 820 may have circular open structures, that is, the second through-holes 816 and 826. The output terminals 520, 620, 720, and 760 of the RF magnetic sensors 501, 502, 601, 602, 701, and 702 are positioned within the open structures 816 and 826 of the rear covers 815 and 825 of the non-magnetic protective cases 810 and 820, and the output terminals 520, 620, 720, and 760 may be connected to external RF cables (not shown).

Referring to FIG. 23, to implement and manufacture the RF magnetic sensor 501, 502, 601, 602, 701, and 702 as a two-axis sensor, the x-axis RF magnetic sensors 501, 502, 601, 602, 701, and 702 and the y-axis RF magnetic sensors 501, 502, 601, 602, 701, and 702 need to be arranged at a perpendicular angle of 90 degrees to each other. The non-magnetic protective case 810 coupled with the RF magnetic sensors 501, 502, 601, 602, 701, and 702 may be positioned along the x-axis, and the non-magnetic protective case 820 combined with the RF magnetic sensor 501, 502, 601, 602, 701, or 702 may be positioned along the y-axis so that they form a perpendicular configuration.

To maintain the perpendicular orientation of the RF magnetic sensors 501, 502, 601, 602, 701, and 702, the non-magnetic protective cases 810 and 820 combined with the RF magnetic sensors may be coupled to a two-axis fixing jig 840. In this case, the material of the two-axis fixing jig 840 may be a non-magnetic insulating material.

A part of the interior of the two-axis fixing jig 840 may have open structures 841 and 842 through which the RF magnetic sensors 501, 502, 601, 602, 701, and 702 can penetrate in the x-axis and y-axis directions. That is, the two-axis fixing jig 840 may have fixing jig through-holes 841 and 842 formed within it. For example, the non-magnetic case 810 combined with the RF magnetic sensor 501, 502, 601, 602, 701, 702 may penetrate the open structure at the lower part of the two-axis fixing jig, that is, the first fixing jig through-hole 841, and be coupled along the x-axis direction. Similarly, the non-magnetic case 820 combined with the RF magnetic sensor 501, 502, 601, 602, 701, 702 may penetrate the open structure at the upper part of the two-axis fixing jig, that is, the second fixing jig through-hole 842, and be coupled along the y-axis direction.

Referring to FIG. 24, the RF magnetic sensors combined with the two-axis fixing jig 840 may be coupled to a two-axis outer case 850 to complete the two-axis RF magnetic sensor 800.

The shape of the two-axis outer case 850 may be rectangular, circular, elliptical, or other shapes. Additionally, the material of the two-axis outer case 850 may be a non-magnetic insulating material.

For example, the two-axis outer case 850 may be composed of two pieces: the bottom surface of the lower portion of the two-axis outer case, that is, a base plate 852, and the upper and side portion of the two-axis outer case, that is, a cover plate 851. For example, the bottom surface of the lower part of the two-axis fixing jig 840 may be combined and fixed to the bottom surface 852 of the lower part of the two-axis outer case 850. The upper and side part 851 of the two-axis outer case 850 may be combined with the bottom surface 852 of the lower part of the two-axis outer case 850 in a manner that covers the two-axis fixing jig 840.

To manufacture and complete the two-axis RF magnetic sensor 801, the front side of the two-axis outer case 850 may include output ports O1 and O11 for the x-axis and y-axis, respectively. For example, the two-axis RF magnetic sensor 801 may be manufactured using the basic RF magnetic sensors 501, 502 or the dual RF magnetic sensors 601, 602.

The x-axis output port O1 on the front side of the two-axis outer case 850 may connect to the output terminal 520 or 620 of the x-axis RF magnetic sensor located on the rear cover 815 of the non-magnetic protective case 810 via an RF cable (not shown).

Similarly, the y-axis output port O11 on the front side of the two-axis outer case 850 may connect to the output terminal 520 or 620 of the y-axis RF magnetic sensor located on the rear cover 825 of the non-magnetic protective case 820 via an RF cable (not shown).

Through the above-described process, the two-axis RF magnetic sensor 801 using the magnetic induction scheme can be completed and manufactured.

In another exemplary embodiment of the present disclosure, to manufacture and complete the two-axis differential RF magnetic sensor 802, the two-axis RF magnetic sensor 802 may be manufactured using the differential RF magnetic sensor 701 or the dual differential RF magnetic sensor 702.

The x-axis output ports O1 and O2 on the front side of the two-axis outer case 850 may connect to the output terminals 720 and 760 of the x-axis RF magnetic sensors 701 and 702 located on the rear cover 815 of the non-magnetic protective case 810 via RF cables (not shown).

Similarly, the y-axis output ports O11 and O12 on the front side of the two-axis outer case 850 may connect to the output terminals 720 and 760 of the y-axis RF magnetic sensors 701 and 702 located on the rear cover 825 of the non-magnetic protective case 820 via RF cables (not shown).

Through the above-described process, the two-axis differential RF magnetic sensor 802 using the MI scheme can be completed and manufactured.

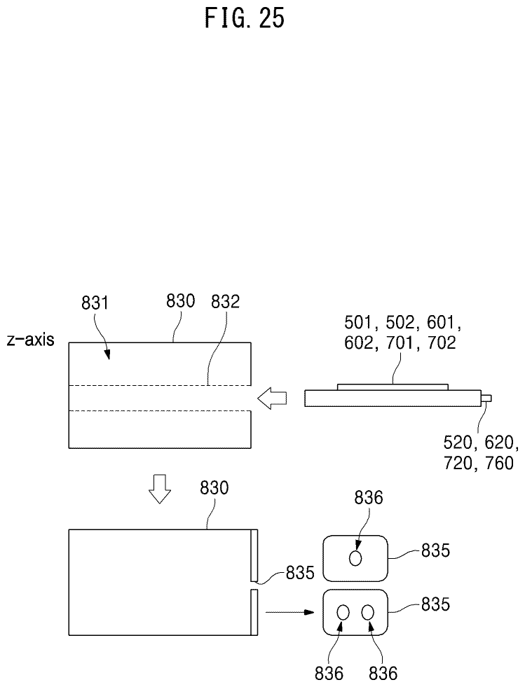

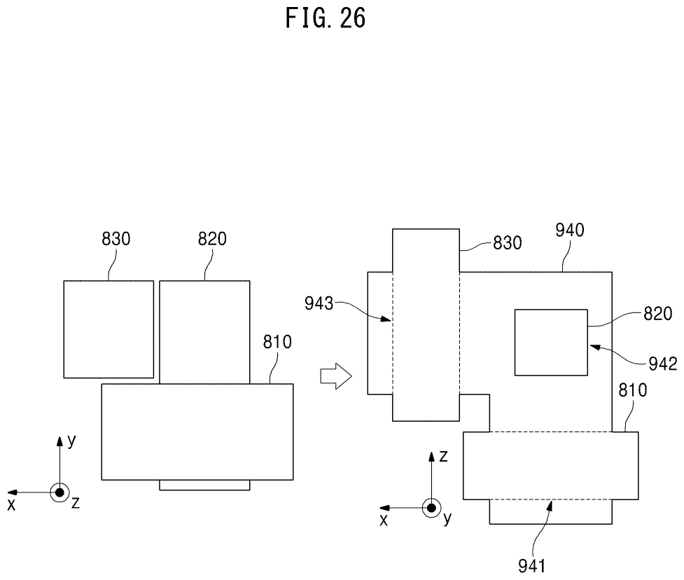

FIG. 25 is a diagram illustrating a manufacturing process of a three-axis RF magnetic sensor using the MI scheme according to an exemplary embodiment of the present disclosure. FIG. 26 is another diagram illustrating the manufacturing process of the three-axis RF magnetic sensor using the MI scheme according to an exemplary embodiment of the present disclosure.

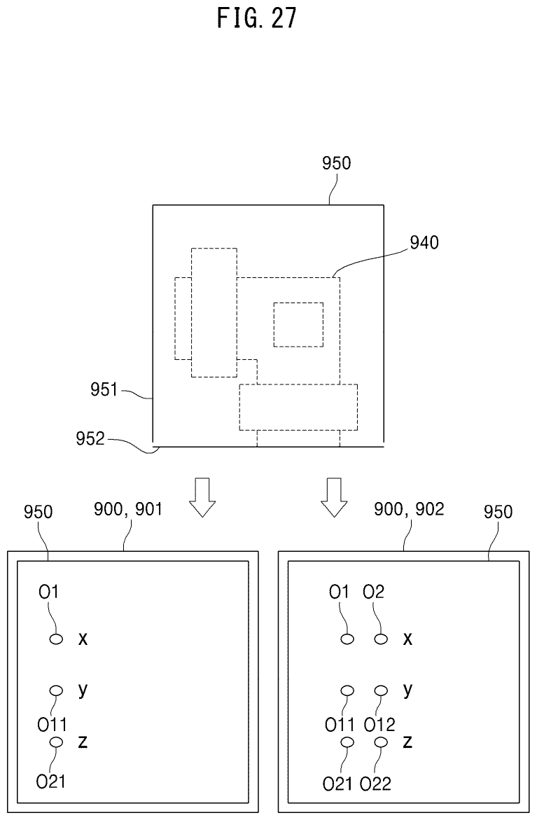

FIG. 27 is a diagram illustrating a housing and input/output ports of the three-axis RF magnetic sensor using the MI scheme according to an exemplary embodiment of the present disclosure.

Hereinafter, FIGS. 25 to 27 will be referred to collectively to describe assembly and manufacturing methods of the three-axis basic, dual, differential, and dual differential RF magnetic sensors using the MI scheme.

To implement and manufacture the three-axis RF magnetic sensor 900 using the MI scheme, the same RF magnetic sensors 501, 502, 601, 602, 701, and 702 may be used for the x-axis, y-axis, and z-axis.

The manufacturing methods for the x-axis and y-axis RF magnetic sensors 501, 502, 601, 602, 701, and 702 in the three-axis RF magnetic sensor are identical to the manufacturing method described for the two-axis RF magnetic sensor in FIG. 22.

The manufacturing method for the z-axis RF magnetic sensor in the three-axis RF magnetic sensor 900 may proceed as follows.

Referring to FIG. 25, the z-axis RF magnetic sensor 501, 502, 601, 602, 701, 702 may be inserted into and combined with a third inner protective case 830, which is a non-magnetic protective shielding case.

When the RF magnetic sensor 501, 502, 601, 602, 701 or 702 is inserted into and combined with the non-magnetic protective case 830, the RF magnetic sensor 501, 502, 601, 602, 701, or 702 may be inserted into the open internal structure, that is, the first insertion hole 832 of the non-magnetic protective case 830. The output terminal 520, 620, 720, or 760 of the RF magnetic sensor 501, 502, 601, 602, 701, or 702 is combined with the rear cover 835 of the non-magnetic protective case 830.

The interior of the rear cover 835 of the non-magnetic protective case 830 may have a circular open structure, that is, the third through-hole 836. The output terminal 520, 620, 720, or 760 of the RF magnetic sensor 501, 502, 601, 602, 701, or 702 is positioned within the open structure 836 of the rear cover 835 of the non-magnetic protective case 830, and the output terminal 520, 620, 720, 760 may be connected to an external RF cable (not shown).

Referring to FIG. 26, to implement and manufacture the RF magnetic sensor 501, 502, 601, 602, 701, 702 as a three-axis sensor, the x-axis RF magnetic sensor, y-axis RF magnetic sensor, and z-axis RF magnetic sensor need to be arranged at a perpendicular angle of 90 degrees to each other. The non-magnetic protective case 810 combined with the RF magnetic sensor 501, 502, 601, 602, 701, 702 may be positioned along the x-axis, and the non-magnetic protective case 820 combined with the RF magnetic sensor 501, 502, 601, 602, 701, 702 may be positioned along the y-axis. Additionally, the non-magnetic protective case 830 combined with the RF magnetic sensor 501, 502, 601, 602, 701, 702 may be positioned along the z-axis. By arranging them in the x, y, and z-axis directions as described above, the RF magnetic sensors may be configured to be perpendicular to each other.

The RF magnetic sensors 501, 502, 601, 602, 701, 702 may be combined with the three-axis fixing jig 940 to maintain perpendicular orientation. Here, the three-axis fixing jig 940 may be made of a non-magnetic insulating material.

A part of the interior of the three-axis fixing jig 940 may have open structures 941, 942, and 943 through which the RF magnetic sensors 501, 502, 601, 602, 701, or 702 may penetrate in the x-axis, y-axis, and z-axis directions. That is, the three-axis fixing jig 940 may have fixing jig through-holes 941, 942, 943 formed within it. For example, the non-magnetic case 810 combined with the RF magnetic sensor 501, 502, 601, 602, 701, 702 may penetrate the open structure at the lower part of the three-axis fixing jig, that is, the first fixing jig through-hole 941, and be coupled along the x-axis direction. The non-magnetic case 820 combined with the RF magnetic sensor 501, 502, 601, 602, 701, 702 may penetrate the open structure at the upper part of the three-axis fixing jig, that is, the second fixing jig through-hole 942, and be coupled along the y-axis direction. The non-magnetic case 830 combined with the RF magnetic sensor 501, 502, 601, 602, 701, 702 may penetrate the open structure at the top-left part of the three-axis fixing jig, that is, the third fixing jig through-hole 943, and be coupled along the z-axis direction.

Referring to FIG. 27, the RF magnetic sensors combined with the three-axis fixing jig 940 may be combined with a three-axis outer case 950 to complete the three-axis RF magnetic sensor 900.

The shape of the three-axis outer case 950 may be rectangular, circular, elliptical, or other shapes. Additionally, the material of the three-axis outer case 950 may be a non-magnetic insulating material.

For example, the three-axis outer case 950 may be composed of two pieces: the bottom surface of the lower portion of the three-axis outer case, that is, a base plate 952, and the upper and side portion of the three-axis outer case, that is, a cover plate 951. For example, the bottom surface of the lower part of the three-axis fixing jig 940 may be combined and fixed to the bottom surface 952 of the lower portion of the three-axis outer case 950. The upper and side portion 951 of the three-axis outer case 950 may be combined with the bottom surface 952 of the lower part of the three-axis outer case 950 in a manner that covers the three-axis fixing jig 940.

To manufacture and complete the three-axis RF magnetic sensor 901, the front side of the three-axis outer case 950 may include output ports O1, O11, and O21 for the x-axis, y-axis, and z-axis, respectively. For example, the three-axis RF magnetic sensor 901 may be manufactured using the basic RF magnetic sensors 501, 502 or the dual RF magnetic sensors 601, 602.

The x-axis output port O1 on the front side of the three-axis outer case 950 may connect to the output terminal 520 or 620 of the x-axis RF magnetic sensor located on the rear cover 815 of the non-magnetic protective case 810 via an RF cable (not shown).

The y-axis output port O11 on the front side of the three-axis outer case 950 may connect to the output terminal 520 or 620 of the y-axis RF magnetic sensor located on the rear cover 825 of the non-magnetic protective case 820 via an RF cable (not shown).

The z-axis output port O21 on the front side of the three-axis outer case 950 may connect to the output terminal 520 or 620 of the z-axis RF magnetic sensor located on the rear cover 835 of the non-magnetic protective case 830 via an RF cable (not shown).

Through the above-described process, the three-axis RF magnetic sensor 901 using the MI scheme can be completed and manufactured.

In another exemplary embodiment of the present disclosure, to manufacture and complete the three-axis RF magnetic sensor 902, the three-axis RF magnetic sensor 902 may be manufactured using the differential RF magnetic sensor 701 and the dual differential RF magnetic sensor 702.

The x-axis output ports O1 and O2 on the front side of the three-axis outer case 950 may connect to the output terminals 720 and 760 of the x-axis RF magnetic sensor located on the rear cover 815 of the non-magnetic protective case 810 via RF cables (not shown).

The y-axis output ports O11 and O12 on the front side of the three-axis outer case 950 may connect to the output terminals 720 and 760 of the y-axis RF magnetic sensor located on the rear cover 825 of the non-magnetic protective case 820 via RF cables (not shown).

The z-axis output ports O21 and O22 on the front side of the three-axis outer case 950 may connect to the output terminals 720 and 760 of the z-axis RF magnetic sensor located on the rear cover 835 of the non-magnetic protective case 830 via RF cables (not shown).

Through the above-described process, the three-axis RF magnetic sensor 902 using the magnetic induction method can be completed and manufactured.

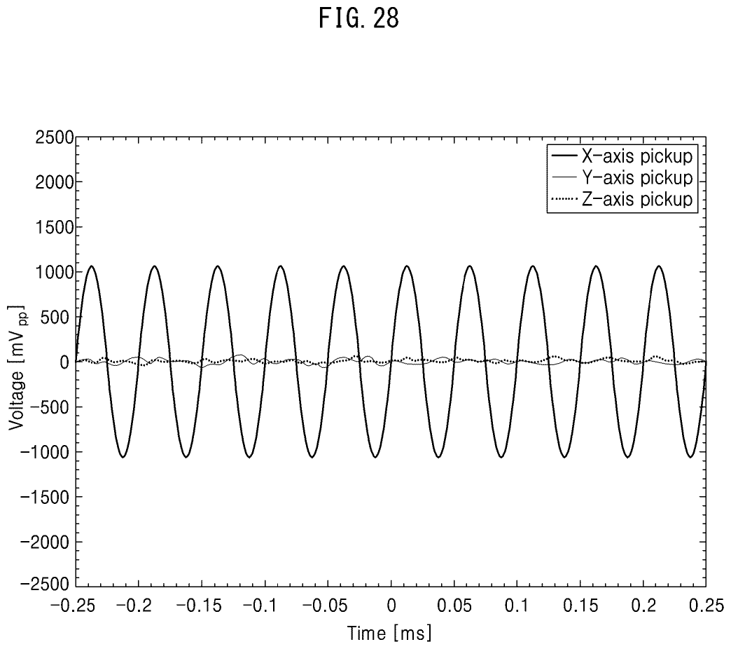

FIG. 28 is a graph illustrating output voltage characteristics of a three-axis RF magnetic sensor using the MI scheme according to an exemplary embodiment of the present disclosure.

Specifically, FIG. 28 shows a graph for the x-axis RF magnetic sensor (X-axis pickup), a graph for the y-axis RF magnetic sensor (Y-axis pickup), and a graph for the z-axis RF magnetic sensor (Z-axis pickup).

The horizontal axis of each graph represents time in milliseconds (ms), and the vertical axis represents voltage in millivolts peak-to-peak (mVₚₚ). In this case, the applied magnetic field corresponding to the external magnetic field may be 100 m Vₚₚ at 20 KHz.

For example, the three-axis RF magnetic sensor 901 may be a sensor composed of the basic RF magnetic sensor 501.

From the graph (X-axis pickup), it can be observed that when an external magnetic field is applied in the x-axis direction, the three-axis RF magnetic sensor 901 senses the external magnetic field in the x-axis direction and converts it into an output voltage characteristic. From the graphs (Y-axis pickup, Z-axis pickup), it is evident that the output voltage characteristic is almost negligible in the y-axis and z-axis directions.

As an example, the graph results in FIG. 28 also show the same output voltage characteristics for the three-axis RF magnetic sensor 401 using the GMI scheme. Therefore, the results in FIG. 28 demonstrate that the three-axis RF magnetic sensor for magnetic field communication proposed in the present disclosure operates independently and without interference across the three axes (x, y, z). Consequently, when the three-axis RF magnetic sensors 401, 402, 901, 902 proposed as receiving elements for magnetic field communication are applied, it can be demonstrated that the receiving element, the three-axis RF magnetic sensor 401, 402, 901, 902, can effectively receive communication signals transmitted in any direction by the transmitter without interference and in a specific direction.

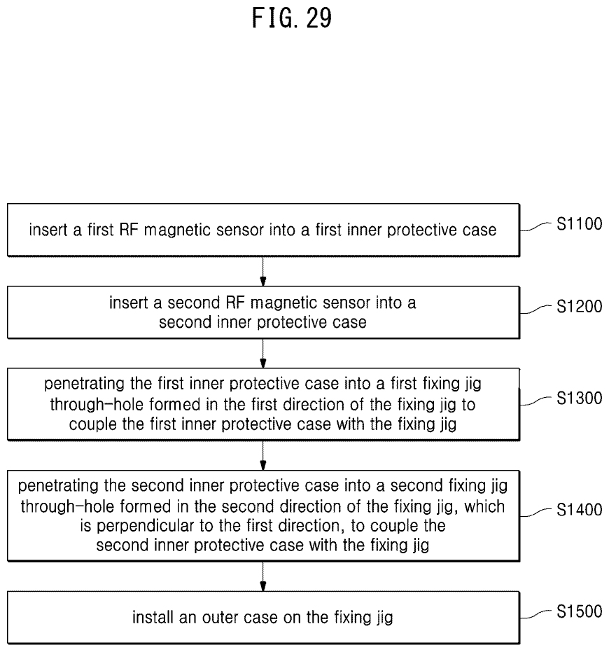

FIG. 29 is a flowchart illustrating a manufacturing method of an RF magnetic sensor for magnetic field communication according to an exemplary embodiment of the present disclosure.

Hereinafter, FIGS. 8 to 13, FIGS. 22 to 27, and FIG. 29 will be referred to collectively for description.

In step S1100, a first RF magnetic sensor may be inserted into a first inner protective case.

In step S1200, a second RF magnetic sensor may be inserted into a second inner protective case.

In steps S1100 and S1200, the first RF magnetic sensor and the second RF magnetic sensor may be either the RF magnetic sensor 100 or 200 using the GMI scheme shown in FIG. 8 or the RF magnetic sensor 501, 502, 601, 602, 701, or 702 using the MI scheme shown in FIG. 22. Additionally, the first inner protective case and the second inner protective case may be either the inner protective cases 310 and 320 shown in FIG. 8 or the inner protective cases 810 and 820 shown in FIG. 22.

In step S1300, the first inner protective case 310 or 810 may be coupled with a fixing jig (e.g. 340 or 840 for two-axis case) by penetrating the first inner protective case into the first fixing jig through-hole 341 or 841 formed in the first direction (x-axis direction) of the fixing jig.

In this case, the materials of the first inner protective case, the second inner protective case, and the fixing jig may include non-magnetic materials.

In step S1400, the second inner protective case 320 or 820 may be coupled with the fixing jig (e.g. 340 or 840 for two-axis case) by penetrating the second inner protective case into the second fixing jig through-hole 342 or 842 formed in the second direction (y-axis direction) perpendicular to the first direction (x-axis direction) of the fixing jig.

In step S1500, the fixing jig 340 or 840 may be installed in the outer case (e.g. 350 or 850).

In this case, prior to step S1100, steps for manufacturing the first RF magnetic sensor and the second RF magnetic sensor may be performed.

In an exemplary embodiment of the present disclosure, the first RF magnetic sensor and the second RF magnetic sensor may be the differential RF magnetic sensor 201 using the GMI scheme or the differential RF magnetic sensor 701 using the MI scheme. In this case, the steps for manufacturing the first RF magnetic sensor 201 or 701 and the second RF magnetic sensor 201 or 701 may respectively include: a step of connecting the first sub-RF magnetic sensor 101, 501, or 502 to the substrate 201 or 711 such that one end of the first pickup coil 104, 204, 513, or 713, which surrounds the ferromagnetic core 102, 202, 512, or 712 of the first sub-RF magnetic sensor 101, 501, or 502, is connected to the output terminal 130, 230, 520, or 720 of the first sub-RF magnetic sensor 101, 501, or 502; and a step of connecting the second sub-RF magnetic sensor 101, 501, or 502 to the substrate 201 or 711 such that one end of the second pickup coil 104, 254, 513, or 753, which surrounds the ferromagnetic core 102, 252, 512, or 752 of the second sub-RF magnetic sensor 101, 501, or 502, is connected to the output terminal 130, 280, 520, or 760 of the second sub-RF magnetic sensor 101, 501, or 502.

In another exemplary embodiment of the present disclosure, the first RF magnetic sensor and the second RF magnetic sensor may be the dual RF magnetic sensor 601 or 602 using the MI scheme. In this case, the steps for manufacturing the first RF magnetic sensor 601 or 602 and the second RF magnetic sensor 601 or 602 may respectively include: a step of connecting the first ferromagnetic core 612, on which the first pickup coil 613 is wound, to the substrate 611; a step of connecting one end of the first pickup coil 613 to the output terminal 620 of the dual RF magnetic sensor 601 or 602; a step of connecting the second ferromagnetic core 632, on which the second pickup coil 633 is wound, to the substrate 611; and a step of connecting one end of the second pickup coil 633, corresponding to one end of the first pickup coil 613, to the output terminal 620 of the dual RF magnetic sensor 601 or 602.

In yet another exemplary embodiment of the present disclosure, the first RF magnetic sensor and the second RF magnetic sensor may be the dual differential RF magnetic sensor 702 using the MI scheme. In this case, the first RF magnetic sensor 702 and the second RF magnetic sensor 702 may each include an additional second dual RF magnetic sensor in addition to the dual RF magnetic sensor described above. The steps for manufacturing the first RF magnetic sensor 702 and the second RF magnetic sensor 702 may respectively include: a step of connecting the first ferromagnetic core 612 or 752, on which the first pickup coil 613 or 753 of the second dual RF magnetic sensor 601, 602 is wound, to the substrate 711; a step of connecting the second ferromagnetic core 632, 772, on which the second pickup coil 633 or 773 of the second dual RF magnetic sensor 601, 602 is wound, to the substrate 711; a step of connecting the other end of the first pickup coil 713 of the dual RF magnetic sensor, corresponding to the other one end of the first pickup coil 753 of the second dual RF magnetic sensor, to the output terminal 760 of the second dual RF magnetic sensor; and a step of connecting the other end of the second pickup coil 773 of the second dual RF magnetic sensor, corresponding to the other end of the first pickup coil 753, to the output terminal 760 of the second dual RF magnetic sensor.

Through steps S1100 to S1500, a two-axis RF magnetic sensor may be manufactured.

To manufacture a three-axis RF magnetic sensor, an additional step may be performed between steps S1200 and S1300 to insert a third RF magnetic sensor (e.g. 100 or 200 in FIG. 11 or 501, 502, 601, 602, 701, or 702 in FIG. 25) into a third inner protective case (e.g. 330, 830).

In this case, the fixing jig may be a three-axis fixing jig (e.g. 440, 940).

Additionally, between steps S1400 and S1500, the third inner protective case 330, 830 may be coupled with the fixing jig by penetrating the third inner protective case into the third fixing jig through-hole (e.g. 443 or 943), which is formed in the third direction (z-axis direction) perpendicular to the first direction (x-axis direction) and the second direction (y-axis direction) of the fixing jig 440, 940.

The first inner protective case 310 or 810 in step S1100 may include a body 311 or 811 with a first insertion hole 312 or 812 and a rear cover 315 or 815 attached to one side of the body 311 or 811 where the first insertion hole 312 or 812 is formed. The rear cover 315 or 815 may include a third through-hole 316 or 816.

In step S1100, the first RF magnetic sensor 100, 200, 501, 502, 601, 602, 701, or 702 may be inserted into the first insertion hole 312 or 812 of the body 311 or 811 of the first inner protective case 310 or 810. The output terminal 130, 230, 280, 520, 620, 720, or 760 of the first RF magnetic sensor 100, 200, 501, 502, 601, 602, 701, or 702, exposed through the body 311 or 811, may then be inserted into the third through-hole 316 or 816, and the rear cover 315 or 815 may be attached to the body 311 or 811.

Similarly, the second inner protective case 320 or 820 in step S1200 may include a body 321 or 821 with a first insertion hole 322 or 822 and a rear cover 325 or 825 attached to one side of the body 321 or 821 where the first insertion hole 322 or 822 is formed. The rear cover 325 or 825 may include a third through-hole 326 or 826.

In step S1200, the second RF magnetic sensor 100, 200, 501, 502, 601, 602, 701, or 702 may be inserted into the first insertion hole 322 or 822 of the body 321 or 821 of the second inner protective case 320 or 820. The output terminal 130, 230, 280, 520, 620, 720, or 760 of the second RF magnetic sensor 100, 200, 501, 502, 601, 602, 701, or 702, exposed through the body 321 or 821, may then be inserted into the third through-hole 326 or 826, and the rear cover 325 or 825 may be attached to the body 321 or 821.

For the GMI scheme, the body 311 or 321 of the inner protective cases 310 or 320 may have a first through-hole 312 or 322 open on both sides of the body 311 or 321. For the MI scheme, the body 811 or 821 of the inner protective cases 810 or 820 may have a first insertion hole 812 or 822 open on one side of the body 811 or 821.

In the case of the GMI scheme, the first inner protective case 310 and the second inner protective case 320 may additionally include front covers 313 and 323, which are attached to the other side of the body 311 or 321 and include second through-holes 314 and 324.

In step S1100, the input terminal 120, 220, or 270 of the first RF magnetic sensor 100 or 200 exposed on the other side of the body 311 of the first inner protective case 310 may be inserted into the second through-hole 314, and the front cover 313 may be attached to the body 311. Similarly, in step S1200, the input terminal 120, 220, or 270 of the second RF magnetic sensor 100 or 200 exposed on the other side of the body 321 of the second inner protective case 320 may be inserted into the second through-hole 324, and the front cover 323 may be attached to the body 321.

The outer case in step S1500 (e.g. 350 in FIG. 10, 450 in FIG. 13, 850 in FIG. 24, or 950 in FIG. 27) may include a cover plate 351, 451, 851, 951 and a base plate 352, 452, 852, 952.

On one side of the cover plate 351, 451, 851, 951, at least one of the input ports and output ports for the first RF magnetic sensor 100, 200, 501, 502, 601, 602, 701, 702 and the second RF magnetic sensor 100, 200, 501, 502, 601, 602, 701, 702 may be formed.

For the giant magnetoimpedance scheme, the input ports (e.g. for a two-axis basic type: I1, I11; for a two-axis differential type: I1, I2, I11, I12; for a three-axis basic type: I1, I11, I21; for a three-axis differential type: I1, I2, I11, I12, I21, I22) and output ports (e.g. for a two-axis basic type: O1, O11; for a two-axis differential type: O1, O2, O11, O12; for a three-axis basic type: O1, O11, O21; for a three-axis differential type: O1, O2, O11, O12, O21, O22) for the first RF magnetic sensor 100, 200 and the second RF magnetic sensor 100, 200 may be formed on one side of the cover plate 351, 451.

In the case of the magnetic induction scheme, one side of the cover plate 851, 951 may include output ports for the first RF magnetic sensor 501, 502, 601, 602, 701, 702 and the second RF magnetic sensor 501, 502, 601, 602, 701, 702. For example, the output ports may include O1 and O11 for the two-axis basic/dual type; O1, O2, O11, and O12 for the two-axis differential/dual differential type; O1, O11, and O21 for the three-axis basic/dual type; and O1, O2, O11, O12, O21, and O22 for the three-axis differential/dual differential type.

Step S1500 may include a step of positioning the fixing jig 340, 440, 840, 940 on the base plate 352, 452, 852, 952 and combining the base plate 352, 452, 852, 952 with the cover plate 351, 451, 851, 951, and a step of connecting at least one of the input ports and output ports to the corresponding input terminals and output terminals of the first RF magnetic sensor and the second RF magnetic sensor via RF cables (not shown).

For example, in the case of the three-axis differential type using the giant magnetoimpedance scheme, the input ports I1, I2, I11, I12, I21, and I22 and output ports O1, O2, O11, O12, O21, and O22 of the cover plate 451 may be connected to the input terminals 220, 270 and output terminals 230, 280 of the first RF magnetic sensor and the second RF magnetic sensor via RF cables.

For example, in the case of the three-axis dual differential type using the magnetic induction scheme, the output ports O1, O2, O11, O12, O21, and O22 of the cover plate 951 may be connected to the output terminals 720, 760 of the first RF magnetic sensor and the second RF magnetic sensor via RF cables.

According to an exemplary embodiment of the present disclosure, an RF magnetic sensor may be provided that extends a single-axis RF magnetic sensor to a two-axis and three-axis magnetic sensor, enabling omnidirectional signal detection or facilitating specific directional signal detection.

According to an exemplary embodiment of the present disclosure, two-axis and three-axis RF magnetic sensors for magnetic field communication and their manufacturing methods may be provided, which can detect RF communication signals in all directions and enable medium-to-long distance magnetic field communication.

According to an exemplary embodiment of the present disclosure, the performance of magnetic sensors can be improved to extend a transmission distance for magnetic field communication, and RF magnetic sensors and their manufacturing methods for increasing the transmission distance can be provided. Specifically, the physical limitation of short transmission distances in magnetic field communication technology can be overcome, allowing the transmission distance to be extended.

According to an exemplary embodiment of the present disclosure, RF magnetic sensors capable of extending a communication distance for magnetic field communication in a VLF/LF band from tens of meters to hundreds of meters can be provided.

According to an exemplary embodiment of the present disclosure, RF magnetic sensors utilizing the giant magnetoimpedance scheme and the magnetic induction scheme with pico-tesla-level ultra-high sensitivity characteristics can be provided.

The description of the disclosure is merely exemplary in nature and, thus, variations that do not depart from the substance of the disclosure are intended to be within the scope of the disclosure. Such variations are not to be regarded as a departure from the spirit and scope of the disclosure. Thus, it will be understood by those of ordinary skill in the art that various changes in form and details may be made without departing from the spirit and scope as defined by the following claims.

What is claimed is:

1. A radio frequency (RF) magnetic sensor for magnetic field communication, comprising:
a first RF magnetic sensor;
a second RF magnetic sensor;
a first inner protective case into which the first RF magnetic sensor is inserted and with which the first RF magnetic sensor is combined;
a second inner protective case into which the second RF magnetic sensor is inserted and with which the second RF magnetic sensor is combined;
a fixing jig in which the first inner protective case is coupled by penetrating in a first direction, and the second inner protective case is coupled by penetrating in a second direction perpendicular to the first direction; and
an outer case for protecting the fixing jig by enclosing the fixing jig inside.

2. The RF magnetic sensor according to claim 1, further comprising:
a third RF magnetic sensor; and
a third inner protective case,
wherein the third RF magnetic sensor is inserted into and combined with the third inner protective case, and the third inner protective case is coupled with the fixing jig by penetrating the fixing jig in a third direction respectively perpendicular to the first direction and the second direction.

3. The RF magnetic sensor according to claim 1, wherein one inner protective case of the first inner protective case or the second inner protective case includes a body and a rear cover combined with a first side among both sides of the body, a first insertion hole for inserting an RF magnetic sensor of the one inner protective case is formed on the first side of the body, with which the rear cover is combined, a third through-hole extended from the first insertion hole is formed on the rear cover, the RF magnetic sensor of the one inner protective case is inserted into the first insertion hole, and an output terminal of the RF magnetic sensor of the one inner protective case penetrates the third through-hole.

4. The RF magnetic sensor according to claim 3, wherein the one inner protective case further includes a front cover combined with a second side among the both sides of the body, the first insertion hole extends to the second side of the body to form a first through-hole, the front cover has a second through-hole formed extending from the first through-hole on the second side of the body, and the output terminal and an input terminal of the RF magnetic sensor inserted into the first through-hole of the body are respectively arranged through the third through-hole of the rear cover and the second through-hole of the front cover.

5. The RF magnetic sensor according to claim 4, wherein the outer case includes a cover plate and a bottom plate, at least one of input ports or output ports for each of the first RF magnetic sensor and the second RF magnetic sensor is formed on one side of the cover plate, and at least one of the input ports and output ports is connected to a corresponding input terminal or output terminal of the first RF magnetic sensor and the second RF magnetic sensor via an RF cable.

6. The RF magnetic sensor according to claim 1, wherein the first RF magnetic sensor and the second RF magnetic sensor are RF magnetic sensors based on a giant magneto-impedance (GMI) scheme or a magnetic induction scheme.

7. The RF magnetic sensor according to claim 1, wherein materials of the first inner protective case, the second inner protective case, and the fixing jig include a non-magnetic material.

8. The RF magnetic sensor according to claim 1, wherein one RF magnetic sensor of the first RF magnetic sensor or the second RF magnetic sensor includes a first sub-RF magnetic sensor and a second sub-RF magnetic sensor connected to a single substrate, a first end among both ends of a first pickup coil surrounding a ferromagnetic core of the first sub-RF magnetic sensor is connected to an output terminal of the first sub-RF magnetic sensor, and a second end among both ends of a second pickup coil surrounding a ferromagnetic core of the second sub-RF magnetic sensor, which corresponds to a second end among the both ends of the first pickup coil, is connected to an output terminal of the second sub-RF magnetic sensor.

9. The RF magnetic sensor according to claim 1, wherein one RF magnetic sensor of the first RF magnetic sensor or the second RF magnetic sensor is a dual RF magnetic sensor, and the dual RF magnetic sensor includes: two ferromagnetic cores connected to a single substrate and two pickup coils each surrounding the two ferromagnetic cores, a first end among both ends of a first pickup coil surrounding a first ferromagnetic core among the two ferromagnetic cores is connected to an output terminal of the dual RF magnetic sensor, and a first end among both ends of a second pickup coil surrounding a second ferromagnetic core among the two ferromagnetic cores, which corresponds to the first end of the first pickup coil, is connected to the output terminal of the dual RF magnetic sensor.

10. The RF magnetic sensor according to claim 9, wherein one RF magnetic sensor among the first RF magnetic sensor and the second RF magnetic sensor further includes a second dual RF magnetic sensor connected to the substrate, a second end among both ends of a first pickup coil of the second dual RF magnetic sensor, which corresponds to a second end among the both ends of the first pickup coil of the dual RF magnetic sensor, is connected to an output terminal of the second dual RF magnetic sensor, and a second end among both ends of a second pickup coil of the second dual RF magnetic sensor is connected to the output terminal of the second dual RF magnetic sensor.

11. A method for manufacturing a radio frequency (RF) magnetic sensor for magnetic field communication, comprising:
inserting a first RF magnetic sensor into a first inner protective case;
inserting a second RF magnetic sensor into a second inner protective case;
coupling the first inner protective case with a fixing jig by penetrating the first inner protective case into a first fixing jig through-hole formed in a first direction of the fixing jig;
coupling the second inner protective case with the fixing jig by penetrating the second inner protective case into a second fixing jig through-hole formed in a second direction perpendicular to the first direction of the fixing jig; and
installing an outer case on the fixing jig.

12. The method according to claim 11, further comprising:
inserting a third RF magnetic sensor into a third inner protective case; and
coupling the third inner protective case with the fixing jig by penetrating the third inner protective case into a third fixing jig through-hole formed in a third direction respectively perpendicular to the first direction and the second direction of the fixing jig.

13. The method according to claim 11, wherein the first inner protective case includes a body in which a first insertion hole is formed, and a rear cover that is combined with a first side among both sides of the body where the first insertion hole is formed and has a third through-hole, and the inserting of the first RF magnetic sensor into the first inner protective case comprises:
inserting the first RF magnetic sensor into the first insertion hole of the body; and
combining the rear cover with the body by inserting an output terminal of the first RF magnetic sensor, which is exposed from the body, into the third through-hole.

14. The method according to claim 13, wherein the first inner protective case further includes a front cover that is connected with a second side of the both sides of the body and has a second through-hole, and the inserting of the first RF magnetic sensor into the first inner protective case comprises: combining the front cover with the body by inserting an input terminal of the first RF magnetic sensor, which is exposed from the second side of the body, into the second through-hole.

15. The method according to claim 14, wherein the outer case includes a cover plate and a bottom plate, and at least one of input ports or output ports for each of the first RF magnetic sensor and the second RF magnetic sensor is formed on one side of the cover plate, and the installing of the outer case on the fixing jig comprises:
positioning the fixing jig on the bottom plate and combining the bottom plate with the cover plate; and
connecting at least one of the input ports and output ports to a corresponding input terminal or output terminal of the first RF magnetic sensor or the second RF magnetic sensor via an RF cable.

16. The method according to claim 11, wherein the first RF magnetic sensor and the second RF magnetic sensor are RF magnetic sensors based on a giant magneto-impedance (GMI) scheme or a magnetic induction scheme.

17. The method according to claim 11, wherein materials of the first inner protective case, the second inner protective case, and the fixing jig include a non-magnetic material.

18. The method according to claim 11, further comprising: before inserting the first RF magnetic sensor into the first inner protective case, manufacturing each of the first RF magnetic sensor and the second RF magnetic sensor,
wherein the manufacturing comprises:
connecting a first sub-RF magnetic sensor to a substrate such that a first end among both ends of a first pickup coil surrounding a ferromagnetic core of the first sub-RF magnetic sensor is connected to an output terminal of the first sub-RF magnetic sensor; and
connecting a second sub-RF magnetic sensor to the substrate such that a second end among both ends of a second pickup coil surrounding a ferromagnetic core of the second sub-RF magnetic sensor, which corresponds to a second end among the both ends of the first pickup coil, is connected to an output terminal of the second sub-RF magnetic sensor.

19. The method according to claim 11, further comprising: when one RF magnetic sensor of the first RF magnetic sensor or the second RF magnetic sensor includes one dual RF magnetic sensor, manufacturing the dual RF magnetic sensor before inserting the first RF magnetic sensor into the first inner protective case,
wherein the manufacturing of the dual RF magnetic sensor comprises:
connecting a first ferromagnetic core around which a first pickup coil is wound to a substrate;
connecting a first end among both ends of the first pickup coil to an output terminal of the dual RF magnetic sensor;
connecting a second ferromagnetic core around which a second pickup coil is wound to the substrate; and
connecting a first end among both ends of the second pickup coil, which corresponds to the first end of the first pickup coil, to the output terminal of the dual RF magnetic sensor.

20. The method according to claim 19, further comprising: when one RF magnetic sensor of the first RF magnetic sensor and the second RF magnetic sensor further includes a second dual RF magnetic sensor, manufacturing the one dual RF magnetic sensor before inserting the first RF magnetic sensor into the first inner protective case,
wherein the manufacturing of the one RF magnetic sensor comprises:
connecting a first ferromagnetic core around which a first pickup coil of the second dual RF magnetic sensor is wound to the substrate, and connecting a second ferromagnetic core around which a second pickup coil of the second dual RF magnetic sensor is wound to the substrate;
connecting a second end among both ends of the first pickup coil of the second dual RF magnetic sensor, which corresponds to a second end among both ends of the dual RF magnetic sensor, to an output terminal of the second dual RF magnetic sensor; and
connecting a second end among both ends of the second pickup coil of the second dual RF magnetic sensor, which corresponds to a second end among both ends of the first pickup coil of the second dual RF magnetic sensor, to the output terminal of the second dual RF magnetic sensor.
